(19) United States
(12) Patent Application Publication
(10) Pub. No.: US 2026/0107405 A1
(43) Pub. Date: Apr. 16, 2026

(54) MANAGING CONNECTIONS OF ELECTRONIC DEVICES WITH COMPUTING DEVICES

(71) Applicant: Aivres Systems Inc., Fremont, CA (US)

(72) Inventor: MINGLI TSAI, New Taipei City (TW)

(21) Appl. No.: 19/421,277

(22) Filed: Dec. 16, 2025

(51) Int. Cl. H05K 7/14; G06F 1/183

(52) U.S. Cl. CPC H05K 7/1487; G06F 1/183

(57) ABSTRACT

Devices, systems, methods, and techniques for managing connections of electronic devices with computer devices are provided. In one aspect, a device includes a base attachable to a computing device, a cover attached to the base, one or more rotatable levers attached to the base, and one or more fasteners. The cover includes one or more guiding trenches extending along a first direction. Each rotatable lever of the one or more rotatable levers includes a respective guiding rail. The one or more fasteners are arranged along a second direction intersecting the first direction. A fastener of the one or more fasteners includes a guiding pin configured to be within a guiding rail of a rotatable lever. The rotatable lever is rotatable to cause the guiding pin of the fastener to move along the guiding rail to thereby move the fastener along the first direction in a guiding trench of the cover.

### TECHNICAL FIELD

The present disclosure is related to computing devices.

### BACKGROUND

Computing devices, such as servers, industrial control systems, and deep learning platforms, are widely used in a variety of fields. In areas such as artificial intelligence (AI) and big data, the need for computing is growing rapidly. These computing devices generally requires multiple external electronic devices connected to the devices to support intensive computational workloads.

### SUMMARY

The present disclosure describes devices, systems, methods, and techniques for managing connections of electronic devices with a computer device and/or a computing system, e.g., securing the electronic devices to the computing device and/or the computing systems, and/or removing any one of the electronic devices from the computing device and/or the computing system.

One aspect of the present disclosure features a device. The device includes a base attachable to a computing device; a cover attached to the base, where the cover includes one or more guiding trenches extending along a first direction; one or more rotatable levers attached to the base, where each rotatable lever of the one or more rotatable levers includes a respective guiding rail; and one or more fasteners that are arranged along a second direction intersecting the first direction, where a fastener of the one or more fasteners includes a guiding pin configured to be within a guiding rail of a rotatable lever, and where the rotatable lever is rotatable to cause the guiding pin of the fastener to move along the guiding rail to thereby move the fastener along the first direction in a guiding trench of the cover.

In some implementations, the device is configured to be assembled to a riser module that is attachable to the computing device, and the base is attachable to the computing device through the riser module.

In some implementations, the guiding rail of the rotatable lever defines a curved path such that a movement of the fastener along the first direction is caused by a rotation of the rotatable lever.

In some implementations, a degree of the rotation of the rotatable lever is in a range from 0° to 70°.

In some implementations, a curved length of the curved path is in a range from 5 mm to 12 mm, and where a length of the movement of the fastener along the first direction is in a range from 0 mm to 4 mm.

In some implementations, the rotatable lever includes a hole, where the rotatable lever is attached to the base by a rotatable screw through the hole, and where the rotatable lever is configured to rotate with respect to the rotatable screw.

In some implementations, the guiding pin is on a first side of the fastener, where the fastener further includes a first notch and a second notch on a second side of the fastener opposite to the first side along a third direction intersecting with the first direction and the second direction, and where the first notch and the second notch are arranged along the first direction and separated by a spacer.

In some implementations, the first notch is configured to secure an electronic component to the computing system, and where the fastener is configured to move between an open position and a closed position corresponding to a rotation of the rotatable lever, and where the first notch is configured to secure the electronic component to the computing device when the fastener is at the closed position, and the electronic component is removable from the computing device when the fastener is at the open position.

In some implementations, the base includes one or more pairs of positioning pins, the one or more pairs of positioning pins being separated from each other along the second direction, and where each of the pairs of positioning pins includes at least a first pin and a second pin that are arranged along the first direction.

In some implementations, the fastener further includes a positioning pole extending along the first direction in the second notch, the positioning pole being attached to the spacer along the first direction.

In some implementations, the fastener is coupled to the first pin of a corresponding pair of positioning pins of the base through a spring, where the spring is in contact with the first pin and the spacer along the first direction, and where the positioning pole is surrounded by the spring.

In some implementations, the first pin, the spring, and the positioning pole are configured to limit a range of a first movement of the fastener along the first direction, and where the second pin is configured to limit a range of a second movement of the fastener along the second direction.

In some implementations, the spring is configured to reposition the fastener along the first direction.

In some implementations, along the second direction, a width of the first pin is smaller than a width of the second notch, and where, along the second direction, a width of the second pin is smaller than the width of the second notch.

Another aspect of the present disclosure features a device assembly. The device assembly includes a riser module attachable to a computing device; and a fastening device configured to secure at least one electronic component to the riser module, where the fastening device includes: a base attachable to the riser module; a cover attached to the base, where the cover includes one or more guiding trenches extending along a first direction; one or more rotatable levers attached to the base, where each rotatable lever of the one or more rotatable levers includes a respective guiding rail; and one or more fasteners that are arranged along a second direction intersecting the first direction, where a fastener of the one or more fasteners includes a guiding pin configured to be within a guiding rail of a rotatable lever, and where the rotatable lever is rotatable to cause the guiding pin of the fastener to move along the guiding rail to thereby move the fastener along the first direction in a guiding trench of the cover.

In some implementations, the guiding rail of the rotatable lever defines a curved path such that a movement of the fastener along the first direction is caused by a rotation of the rotatable lever.

In some implementations, a degree of the rotation of the rotatable lever is in a range from 0° to 70°, where a curved length of the curved path is in a range from 5 mm to 12 mm, and where a length of the movement of the fastener along the first direction is in a range from 0 mm to 4 mm.

In some implementations, the rotatable lever includes a hole, where the rotatable lever is attached to the base by a rotatable screw through the hole, and where the rotatable lever is configured to rotate with respect to the rotatable screw.

In some implementations, the guiding pin is on a first side of the fastener, where the fastener further includes a first notch and a second notch on a second side of the fastener opposite to the first side along a third direction perpendicular to the first direction and the second direction, and where the first notch and the second notch are arranged along the first direction and separated by a spacer, and where the first notch is configured to secure an electronic component to the riser module.

In some implementations, the fastener is configured to move between an open position and a closed position corresponding to a rotation of the rotatable lever, and where the first notch is configured to secure the electronic component to the computing device when the fastener is at the closed position, and the electronic component is removable from the computing device when the fastener is at the open position.

Another aspect of the present disclosure features a method of operating a device. The method includes rotating a rotatable lever of a fastening device to cause a guiding pin of a fastener of the fastening device to move within a guiding rail of the rotatable lever along a first direction to thereby move the fastener along the first direction from a closed position to an open position to unlock an electronic component secured to a computing device; and taking the electronic component away from the computing device, where the fastening device includes: a base attachable to the computing device; a cover attached to the base, where the cover includes one or more guiding trenches extending along the first direction; one or more rotatable levers attached to the base, where each rotatable lever of the one or more rotatable levers includes a respective guiding rail, the one or more rotatable levers including the rotatable lever; and one or more fasteners that are arranged along a second direction intersecting the first direction, the one or more fasteners including the fastener, where the rotatable lever is rotatable to cause the guiding pin of the fastener to move along the guiding rail to thereby move the fastener along the first direction in a guiding trench of the cover.

A further aspect of the present disclosure features a system. The system includes a computing device; one or more electronic components; and an electronic device assembly configured to manage a connection of the one or more electronic components with the computing device, where the electronic device assembly includes: a riser module attachable to the computing device; and a fastening device configured to secure the one or more electronic components to the riser module, where the fastening device includes: a base attachable to the riser module; a cover attached to the base, where the cover includes one or more guiding trenches extending along a first direction; one or more rotatable levers attached to the base, where each rotatable lever of the one or more rotatable levers includes a respective guiding rail; and one or more fasteners that are arranged along a second direction intersecting the first direction, where a fastener of the one or more fasteners includes a guiding pin configured to be within a guiding rail of a rotatable lever, and where the rotatable lever is rotatable to cause the guiding pin of the fastener to move along the guiding rail to thereby move the fastener along the first direction in a guiding trench of the cover.

For illustration purposes, the techniques are described with respect to a computing device as an example. Note that the techniques can also be applied to a computing system. The terms “electronic devices” and “electronic components” can be used interchangeably in the present disclosure.

The details of one or more implementations of the subject matter of this specification are set forth in the Detailed Description, the Claims, and the accompanying drawings. Other features, aspects, and advantages of the subject matter will become apparent to those of ordinary skill in the art from the Detailed Description, the Claims, and the accompanying drawings.

### DESCRIPTION OF DRAWINGS

FIG. 1 is a schematic view of an example computing device.

FIG. 2A is a perspective view of an example computing device.

FIG. 2B is a perspective view of an example electronic device assembly.

FIGS. 3A is an exploded view of the electronic device assembly of FIG. 2B.

FIGS. 3B – 3E are perspective views of components of an example fastening device.

FIGS. 4A – 4D illustrate steps of assembling an example fastening device.

FIGS. 5A – 5B illustrate steps of assembling an electronic component to an electronic device assembly.

FIGS. 6A – 6B illustrate steps of disassembling an electronic component from an electronic device assembly.

FIG. 7A is a flowchart of an example process of a method of assembling an electronic component to an electronic device assembly.

FIG. 7B is a flowchart of an example process of a method of disassembling an electronic component from an electronic device assembly.

FIG. 8 illustrates an example computing device.

FIG. 9 illustrates an example computing system

Like reference numbers and designations in the various drawings indicate like elements.

### DETAILED DESCRIPTION

Development in computing technology has led to an increasing demand for larger and more sophisticated network communication architectures. Computing devices that are designed to meet this increasing demand require multiple external electronic devices connected to them to support intensive computational workloads. Electronic devices (e.g., Peripheral Component Interconnect Express (PCIe) devices) can be attached to the computing devices to meet the demand for larger and more sophisticated network communication architectures. The electronic devices can be secured to the computing device to maintain stable data transfer between the electronic devices and the computing device. If the electronic devices are not secured to the computing device, a movement of the computing system may damage the electronic devices or cause errors during data transfer. In some cases, the electronic devices are secured to the computing devices by corresponding screws or latches. During a service or maintenance operation of the computing device, an operator is required to disassemble all outer electronic devices in order to disassemble or assemble a specific electronic device, resulting in increased time of the service or maintenance operation and higher service or maintenance costs. Therefore, a device that can resolve the aforementioned problems is desirable.

Implementations of the present disclosure provide methods, devices, systems, and techniques for managing connections of electronic components with computer devices or systems. In some implementations, a device includes a base attachable to a computing device; a cover attached to the base, where the cover includes one or more guiding trenches extending along a first direction; one or more rotatable levers attached to the base, where each rotatable lever of the one or more rotatable levers includes a respective guiding rail; and one or more fasteners that are arranged along a second direction intersecting the first direction, where a fastener of the one or more fasteners includes a guiding pin configured to be within a guiding rail of a rotatable lever, and where the rotatable lever is rotatable to cause the guiding pin of the fastener to move along the guiding rail to thereby move the fastener along the first direction in a guiding trench of the cover.

Implementations of the present disclosure can provide one or more of the following technical advantages, effects, and/or benefits. For example, each of the electronic components is secured by a respective fastener and a respective rotatable lever. During a service or maintenance operation of the computing system, the operator can rotate a rotatable lever coupled to a corresponding fastener to unlock a specific electronic component. The combination of the rotatable levers and the fasteners of the device can help realize individual control of the electronic components attached to the computing system so that the operator can disassemble or assemble the specific electronic component without moving remaining electronic components. In other words, the combination of the rotatable levers and the fasteners of the device can help reduce service and maintenance time and cost. Additionally, a movement of a fastener is corresponding to a rotation of a corresponding rotatable lever. For example, a horizontal movement of the fastener can be achieved by a rotation of the corresponding rotatable lever. The rotation of the corresponding rotatable lever can be achieved with a small footprint, thereby reducing the size of the device and resulting in a higher electronic component density in the computing system. Furthermore, the device disclosed in the present disclosure can be easily fabricated and integrated into the computing device or system, reducing integration and service costs.

The following detailed description describes systems and techniques for managing connections of electronic components to a computer device or system and is presented to enable any person skilled in the art to make and use the disclosed subject matter in the contact of one or more particular implementations. Various modifications, alterations, and permutations of the disclosed implementations can be made and will be readily apparent to those of ordinary skill in the art, and the general principles defined can be applied to other implementations and applications, without departing from the scope of the present disclosure. In some instances, one or more technical details that are unnecessary to obtain an understanding of the described subject matter and that are within the skill of one of ordinary skill in the art may be omitted so as to not obscure one or more described implementations. The present disclosure is not intended to be limited to the described or illustrated implementations, but to be accorded the widest scope consistent with the described principles and features.

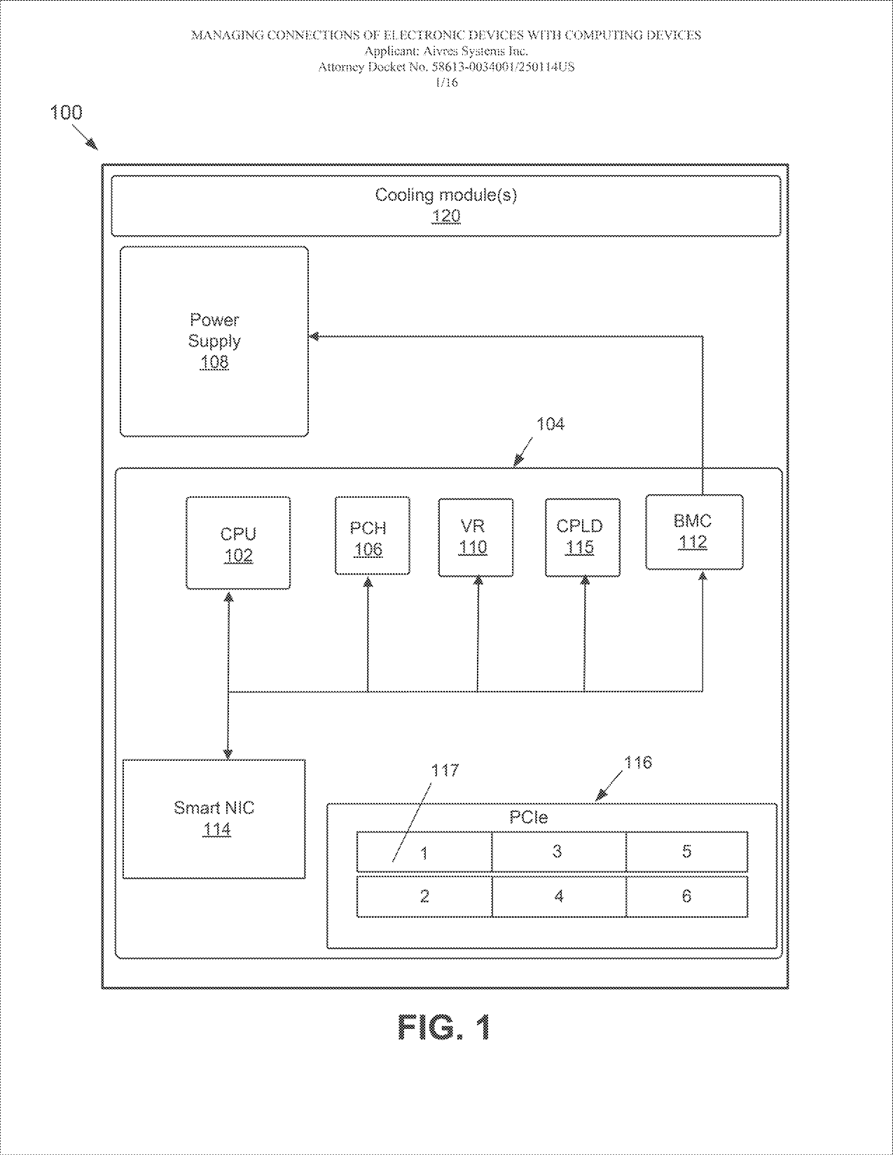

FIG. 1 is a schematic view of an example computing device 100. The computing device 100 includes one or more electronic components. For example, as shown in FIG. 1, one of the one or more electronic components can be a processor 102. As shown in FIG. 1, the processor 102 can be a central processing unit (CPU). Although most of the descriptions below are using the example of CPUs, the described systems and techniques are applicable to other types of processors. In some implementations, the one or more electronic components can be other types of components that are configured to perform different operations of the computing device 100. For example, the one or more electronic components can include one or more CPUs, graphics processing units (GPUs), multi-core processors, microprocessors, quantum processors, storage units (e.g., dynamic random access memory (DRAM)), peripheral component interconnect express (PCIe) devices, or a combination of thereof. The computing device 100 includes a motherboard (MB) 104. The MB 104 can be a main circuit board that connects internal and external components of the computing device 100 and allows them to communicate with one another. For example, the MB 104 can connect one or more processors, memory, graphics card, and other hardware.

One of the one or more electronic components can be a platform controller hub (PCH) 106. The PCH 106 can be mounted on the MB 104 and is configured to manage various input/output (I/O) interfaces on the MB 104 and serve as an intermediary between the processor 102 and peripherals to route data from connected devices. As shown in FIG. 1, the computing device 100 can also include a power supply module 108. The power supply module 108 is electrically coupled to the processor 102 through a voltage regulator (VR) 110. In operation, the power supply module 108 is configured to supply power to the processor 102, and the VR 110 is configured to regulate the power supplied by the power supply module 108 to the processor 102. For example, the VR 110 is configured to maintain a safe operation voltage of the processor 102 during the operation of the computing device 100.

In some implementations, the computing device 100 also includes a Baseboard Management Controller (BMC) 112. The BMC 112 is a microcontroller that provides out-of-band management of the computing device 100. In some implementations, the BMC 112 is configured to provide administrators with remote access and control over hardware, for example, even when the computing device 100 is powered off or unresponsive. The BMC 112 can be accessible by the administrators via a dedicated Ethernet (or local area network (LAN)) port or a shared network interface, thereby allowing secure remote connections.

The computing device 100 can further include a complex programmable logic device (CPLD) 115. The CPLD 115 can be mounted onto the MB 104 and be coupled to the processor 102. The CPLD 115 can include a plurality of programmable logic blocks that are configured to perform various functions controlled by the processor 102. In some implementations, the plurality of programmable logic blocks of the CPLD 115 can be freely programmed by the processor 102, which allows flexibility in designing digital circuits.

As shown in FIG. 1, the computing device 100 also includes a Network Interface Controller (NIC) 114 (e.g., a smart NIC) and a connector circuit 116 for connecting one or more electronic devices. The connector circuit 116 can include one or more connectors 117 for connecting the one or more electronic devices. For example, one connector is configured to connect one electronic device. In some examples, a connector 117 can be a PCIe connector 117 for connecting a corresponding PCIe device, e.g., a GPU, a Storage device, a sound card, a graphic card, a Network Card, or any other suitable electronic device. For illustration purposes, the PCIe connector and the PCIe device are described below as examples of the connector and the electronic device.

The NIC 114 can be mounted on the MB 104. The connector circuit 116 is coupled to the processor 102. In some implementations, each of the PCIe connectors 117 includes a PCIe slot soldered onto the MB 104, where an electronic device is mounted to the MB 104 through the PCIe slot. In some implementations, the NIC 114 can be configured to control the PCIe devices. In some implementations, the NIC 114 also enables the computing device 100 to communicate with other devices on a network. In some implementations, the NIC 114 can be coupled to the processor 102 through one of the PCIe connectors 117 that is soldered onto the MB 104.

In some implementations, the computing device 100 includes one or more cooling modules 120. The one or more cooling modules 120 can include one or more air-cooling modules such as fans and/or one or more liquid-cooling modules such as cooling plates, which can provide cooling for the computing device 100 during operation.

The computing device 100 can be configured to ensure real-time detection of the presence, status, and quantity of the external electronic devices connected to the PCIe connectors 117 or the detector circuit 116 for maintaining the overall system stability and reliability of the computing device 100. In some implementations, the presence, status, and quantity of the external electronic devices connected to the PCIe connectors 117 can be detected by the BMC 112 and/or the CPLD 115.

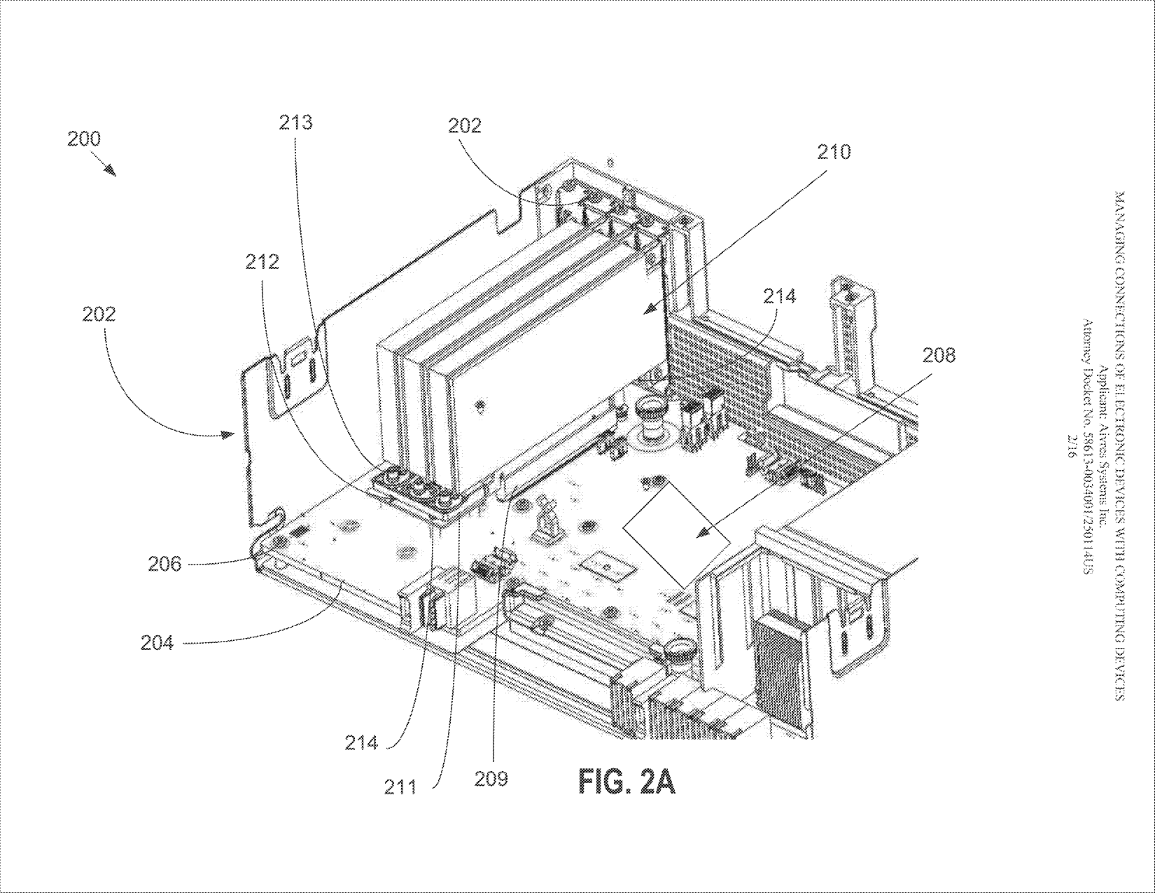

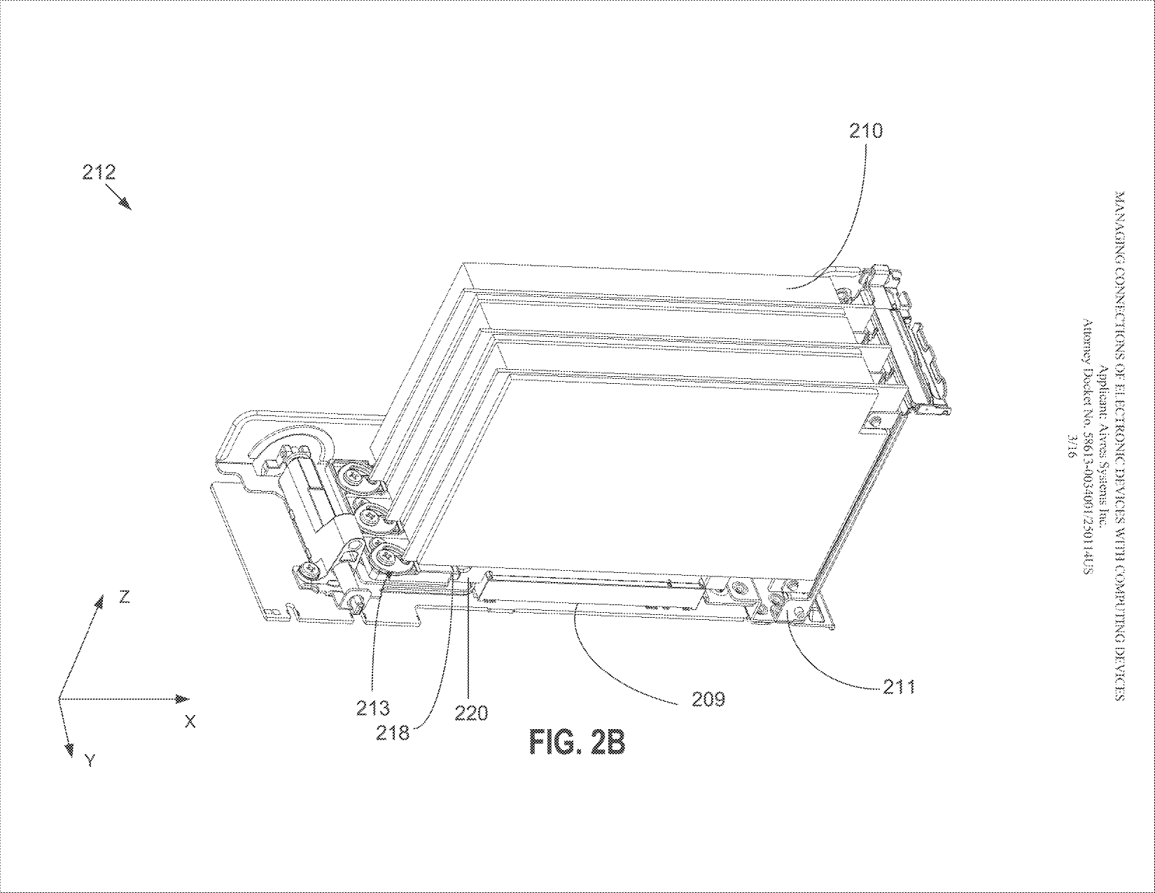

FIG. 2A is a perspective view of a computing device 200. The computing device 200 can be the computing device 100 illustrated in FIG. 1.

As shown in FIG. 2A, the computing device 200 can include a case (or housing) 202 that is configured to hold electronic components of the computing device 200. In some implementations, during operation, the case 202 is configured to secure and protect the electronic components.

The computing device 200 can include a circuit board 204 (e.g., a MB 204). In some implementations, the MB 204 can be similar to, or same as, the MB 104 of the computing device 100 of FIG. 1. During operation, as illustrated in FIG. 2A, the MB 204 can be secured to the case 202 through one or more screws 206.

The computing device 200 also includes a processor 208 attached to the MB 204. The processor 208 can be similar to, or the same as, the processor 102 of the computing device 100 of FIG. 1. As shown in FIG. 2A, the computing device 200 further includes one or more electronic components 210. In some implementations, the one or more electronic components 210 can be PCIe devices that are coupled to the processor 208 through corresponding PCIe connectors 209. In some implementations, the PCIe connectors 209 can be similar to, or the same as, the connectors 117 of the computing device 100 of FIG. 1. The one or more electronic components 210 can be assembled on an electronic device assembly 212. As shown in FIG. 2A, the electronic device assembly 212 includes a fastening device 213 that is configured to secure the one or more electronic components 210. During operation, the electronic device assembly 212 can help prevent movement of the one or more electronic components 210, reducing error rates of the processor 208. For example, each of the one or more electronic components 210 can be coupled to the processor 208 through a corresponding PCIe connector 209 and secured by the fastening device 213.

In some implementations, the electronic device assembly 212 can be arranged at any location in the case 202 to facilitate (e.g., optimize) the arrangement of the electronic components of the computing device 200. In some implementations, as shown in FIG. 2A, the electronic device assembly 212 is secured to the case 202 and the MB 204 through one or more screws 214. In some implementations, the electronic device assembly 212 can include a riser module 211. The riser module 211 is configured to provide a displacement (e.g., vertical or horizontal displacement) between the one or more electronic components 210 and the MB 204, so that the one or more electronic components 210 can be inserted in to one or more corresponding connectors 209. In some examples, the riser module 211 includes a riser card that can be a circuit board, e.g., a PCIe riser, a rigid riser, or a power riser. In some implementations, each of the one or more electronic components 210 is secured by the fastening device 213 to the MB 204 and one or more screws 216 to the case 202.

FIG. 2B illustrates a perspective view of the electronic device assembly 212. As shown in FIG. 2B, during operation, the one or more electronic components 210 and the fastening device 213 are arranged along a first direction (e.g., the X direction). In some implementations, the one or more electronic components 210 are arranged along a second direction (e.g., the Y direction) intersecting with the X direction. In some implementations, as illustrated in FIG. 2B, the fastening device 213 is attached to the riser module 211 along a third direction (e.g., the Z direction) intersecting with the X direction and the Y direction.

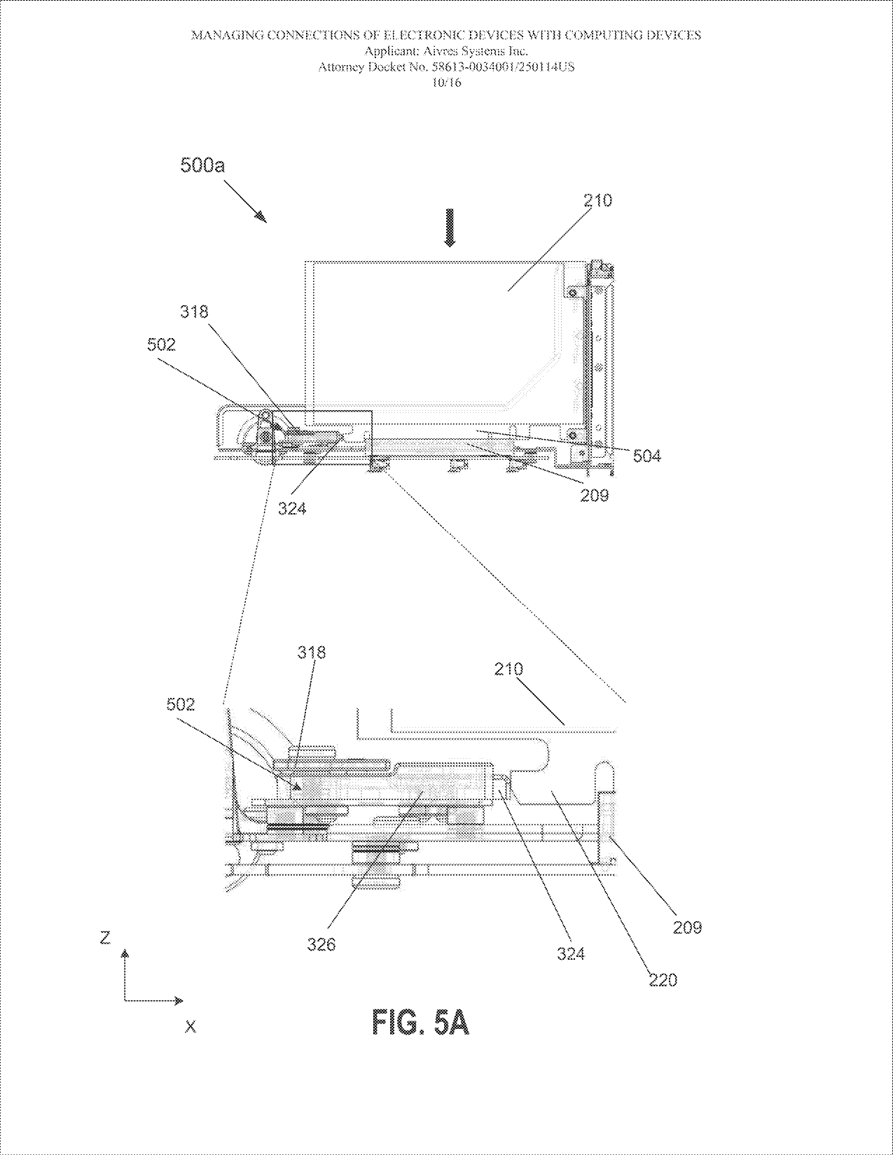

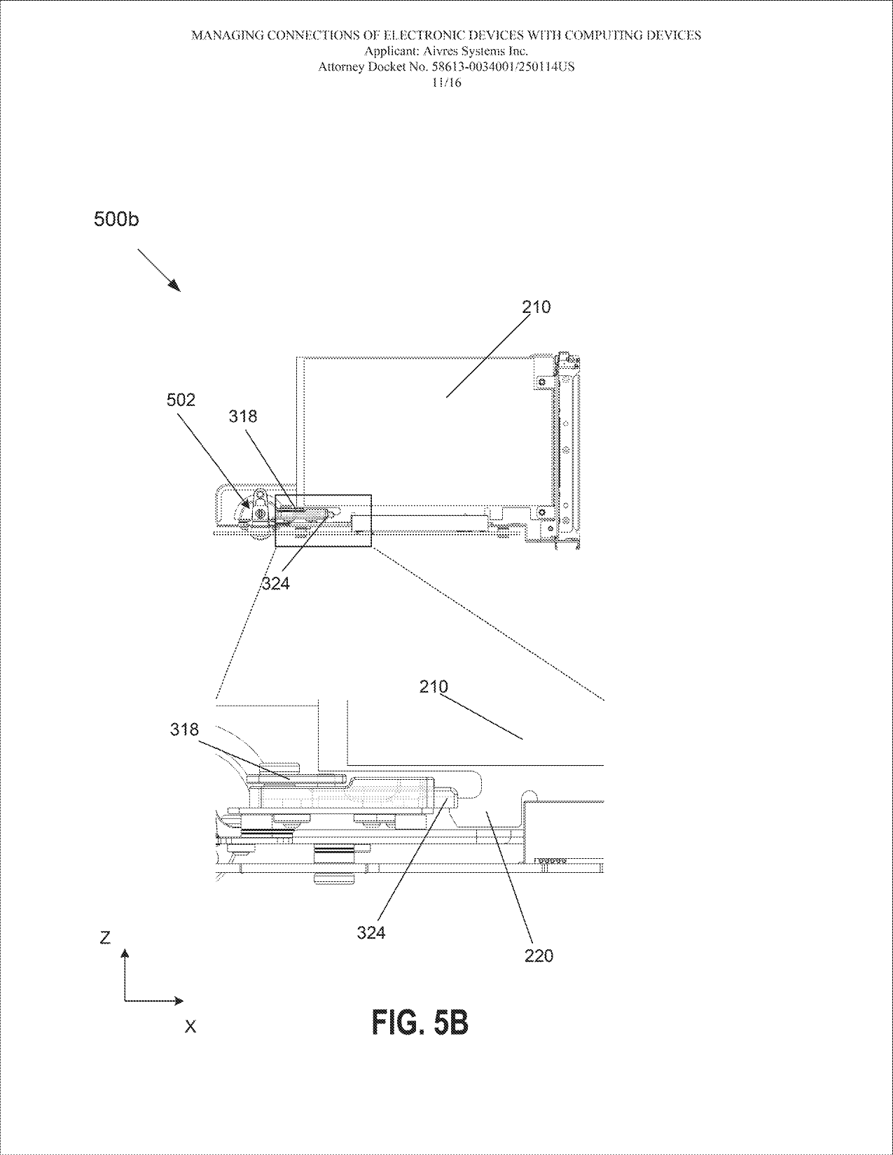

As illustrated in FIG. 2B, the fastening device 213 includes one or more fasteners 218. The one or more fasteners 218 is configured to move along the X direction between a closed position (as illustrated in FIG. 2B) and an open position (as illustrated with further details in FIG. 5A). Each of the one or more fasteners 218 is configured to secure a corresponding electronic component 210 at the closed position. For example, referring to FIG. 2B, an electronic component 210 includes a secure structure 220. The fastener 218 of the fastening device 213 is configured to lock the secure structure 220 of the electronic component 210 when the electronic component 210 is attached to the computing device (e.g., the computing device 200 of FIG. 2A). During operation, the fastener 218 is configured to prevent a movement of the electronic component 210, e.g., prevent a movement along the third direction.

It is understood that FIG. 2B is for illustration propose only and the electronic device assembly 212 can hold any number of electronic components 210 that are arranged along the Y direction, where each of the electronic components 210 is secured by a corresponding fastener 218 of the fastening device 213.

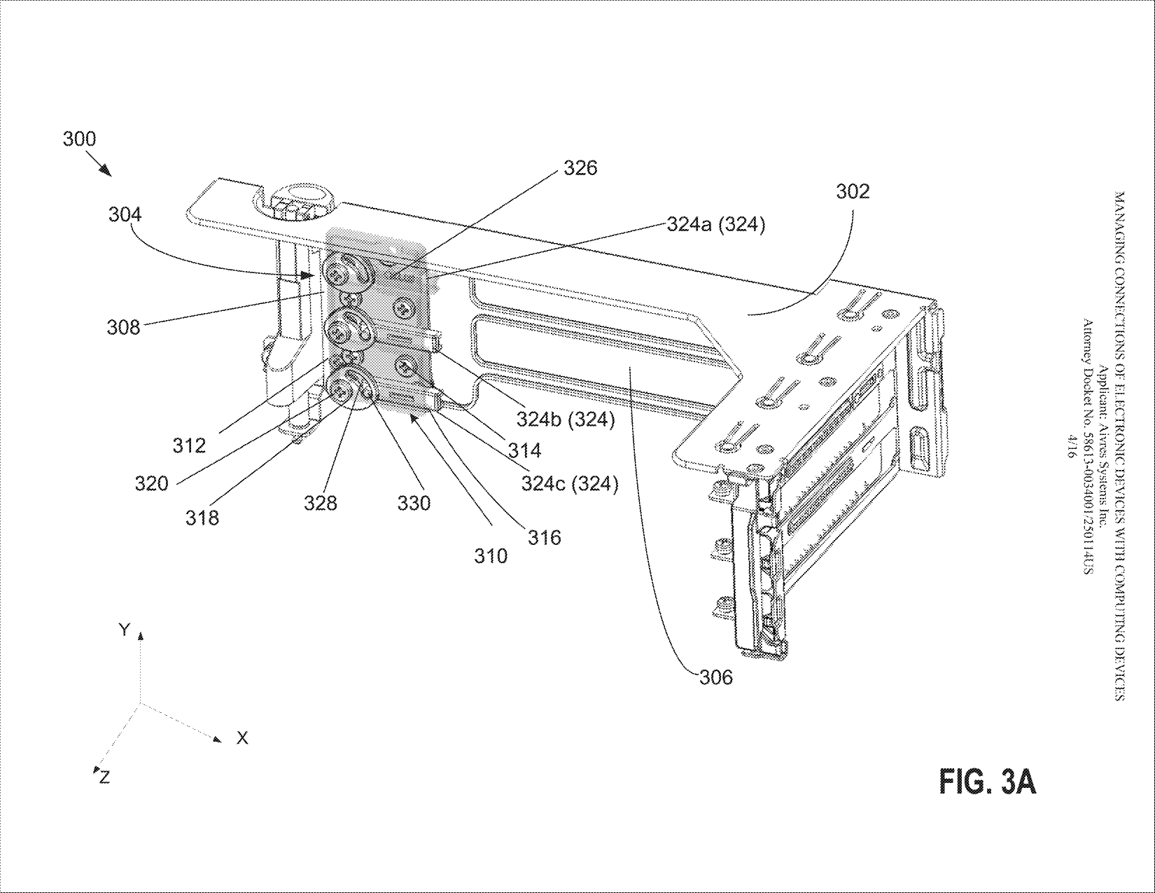

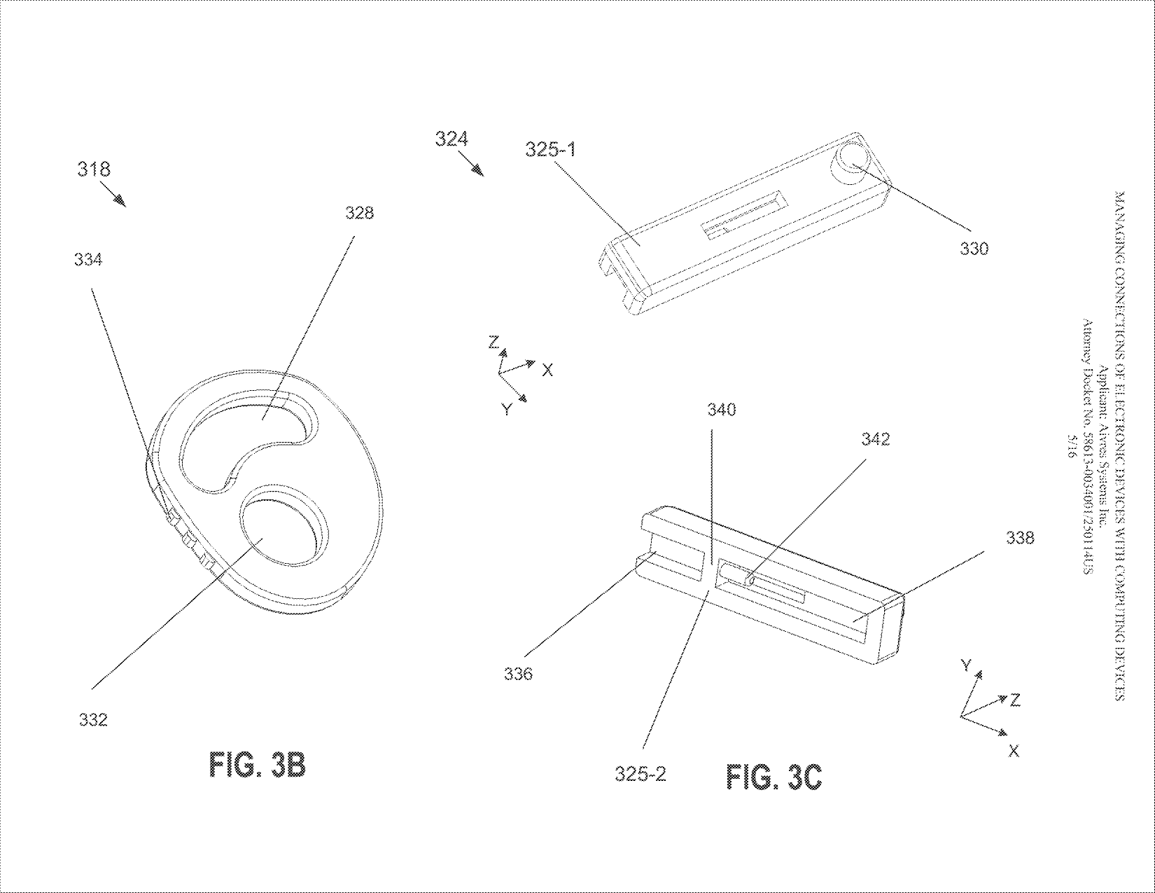

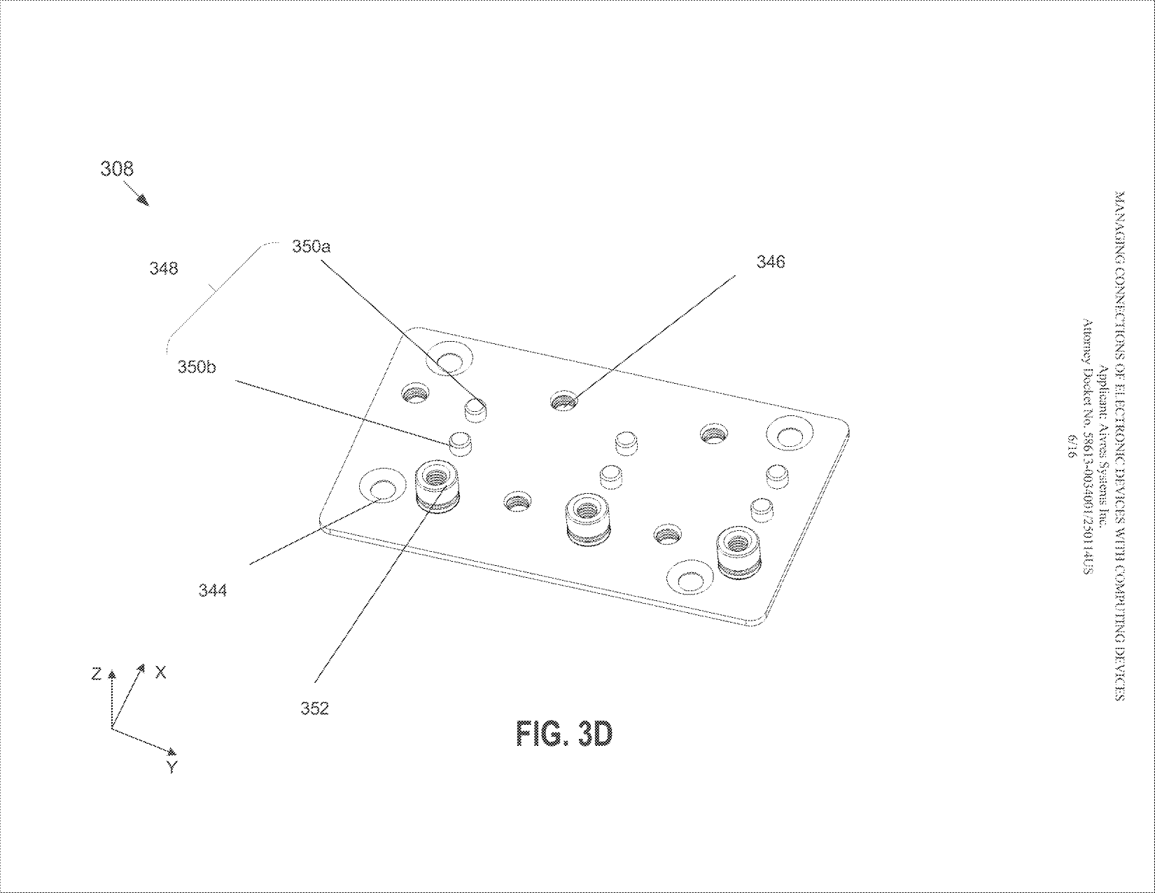

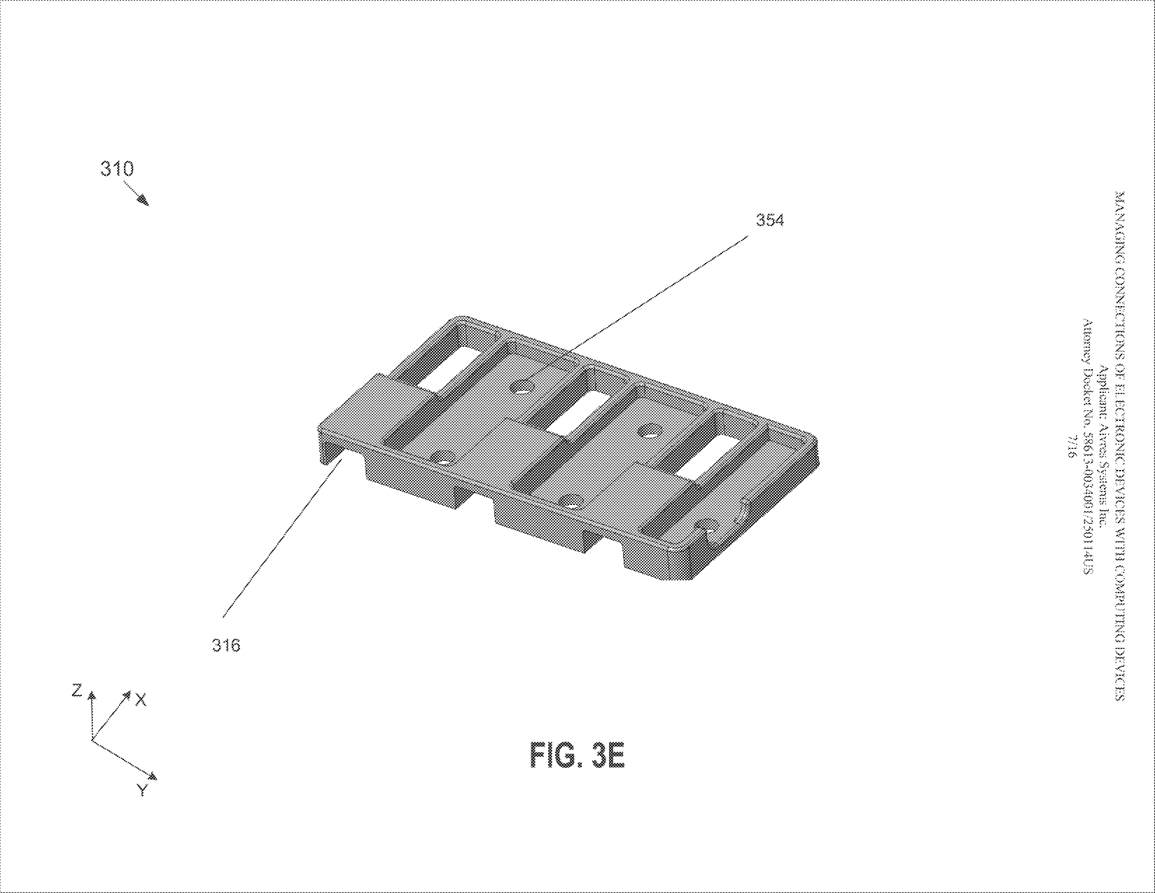

FIGS. 3A is an exploded view of an example electronic device assembly 300. The electronic device assembly 300 can be similar to, or same as, the electronic device assembly 212 of FIG. 2B.

The electronic device assembly 300 includes a riser module 302 and a fastening device 304 attached to the riser module 302. In some implementations, the riser module 302 can be similar to, or same as, the riser module 211 of the electronic device assembly 212 of FIG. 2B. In some implementations, the fastening device 304 can be similar to, or same as, the fastening device 213

of the electronic device assembly 212 of FIG. 2B. As shown in FIG. 3A, the riser module 302 includes one or more trenches 306. In some implementations, during operation, the electronic device assembly 300 is configured to be attached to a circuit board (e.g., the MB 204 of FIG. 2A) and the one or more trenches 306 are configured to provide connection spaces between electronic components (e.g., the electronic components 210 of FIG. 2A) and the connectors (e.g., the PCIe connectors 209 of FIG. 2A).

Referring to FIG. 3A, the fastening device 304 includes a base 308 that is attachable to the riser module 302, a cover 310 attached to the base 308. The base 308 is attached to the riser module 302 by one or more first screws 312, and the cover 310 is secured to the base 308 by one or second screws 314. In some implementations, a second screw 314 can be referred to as a locking screw. As shown in FIG. 3A, the cover 310 includes one or more guiding trenches 316. The one or more guiding trenches 316 extend along the X direction.

In some implementations, the fastening device 304 further includes one or more rotatable levers 318. The one or more rotatable levers 318 are attached to the base 308 by one or more corresponding third screws 320. During operation, each of the one or more rotatable levers 318 is configured to rotate along a plane, e.g., a horizontal plane (e.g., the X-Y plane) perpendicular to the Z direction or a vertical plane (e.g., the Y-Z plane perpendicular to the X direction or a X-Z plane perpendicular to the Y direction), with a corresponding third screw 320. In some examples, a degree of the rotation of the rotatable lever 318 is in a range from 0° to a predetermined angle, e.g., 90°.

The fastening device 304 further includes one or more fasteners 324 that are arranged along the Y direction. As show in FIG. 3A, each of the one or more fasteners 324 is coupled to the base 308 through a corresponding spring 326. In some implementations, each of the one or more fasteners 324 is surrounded by the base 308 and a corresponding guiding trench 316. In some implementations, during operation, the fastener 324 is configured to move along the X direction in the corresponding guiding trench 316 between a closed position and an open position.

Referring to FIG. 3A, each of the one or more rotatable levers 318 includes a respective guiding rail 328. The fastener 324 includes a guiding pin 330. The guiding pin 330 of the fastener 324 is configured to be within the guiding rail 328 of a corresponding rotatable lever 318. In some implementations, the corresponding rotatable lever 318 is rotatable to cause the guiding pin 330 of the fastener 324 to move along the guiding rail 328 to thereby move the fastener 324 along the

X direction in the corresponding guiding trench 316. In some implementations, the guiding rail 328 of the rotatable lever 318 defines a curved path such that a movement of the fastener 324 along the X direction is caused by a rotation of the rotatable lever 318. In some examples, a curved length of the curved path is in a range from 5 mm to 12 mm. In some examples, a length of the movement of the fastener 324 along the X direction is in a range from 0 mm to 4 mm.

For example, during operation, an operator can push a rotatable lever 318 to cause the rotatable lever 318 to rotate along the horizontal plane with respect to a corresponding third screw 320. The rotation of the rotatable lever 318 cause the guiding pin 330 of a corresponding fastener 324 to move along the guiding rail 328 to thereby move the fastener 324 along the X direction towards the rotatable lever 318 in the corresponding guiding trench 316 from the closed position to the open position.

In some implementations, as illustrated in FIG. 3A, the cover 310 is arranged between the base 308 and the one or more rotatable levers 318 along the Z direction. In some implementations, the one or more rotatable levers 318 are attached to the base 308 through the cover 310.

In some implementations, the spring 326 is configured to reposition the fastener 324 along the first direction. For example, during operation, the spring 326 is compressed when the fastener 324 is moved from the closed position to the open position, which is caused by the rotation of the rotatable lever 318. Once the rotatable lever 318 is released, the compressed spring 326 rebounds to cause the fastener 324 to move along the X direction from the open position to the closed position. In some implementations, repositioning the fastener 324 can cause the guiding pin 330 to move along the X direction, thereby causing the rotatable lever 318 to rotate back to the closed position.

As illustrated in FIG. 3A, the fastening device 304 of the electronic device assembly 300 can include any number of fasteners 324, where the guiding pin 330 of each fastener 324 is positioned within the guiding rail 328 of a corresponding rotatable lever 318. During operation, the operator can assemble or disassemble a corresponding electronic component to a specific connector (e.g., the PCIe connectors 209 of FIG. 2B) without interfering with other electronic components. For example, as illustrated in FIG. 3A, the fastening device 304 includes three fasteners 324a–324c. Each of the three fasteners 324a–324c is configured to secure a respective electronic component to the computing system. During a service operation, the operator can disassemble an electronic component secured by a fastener (e.g., fastener 324b) by rotating a corresponding rotatable lever 318 without disassembling remaining electronic components secured by other fasteners (e.g., fasteners 324a and 324c). In other words, the rotatable levers 318 and the fasteners 324 can help achieve individual control of the one or more electronic components of the computing device on the electronic device assembly 300.

It is understood that FIG. 3A is for illustration propose only and the fastening device 304 of the electronic device assembly 300 can include any number of fasteners 324.

FIGS. 3B – 3E are perspective views of components of the fastening device 304 of the electronic device assembly 300 of FIG. 3A.

As illustrated in FIG. 3B, the rotatable lever 318 includes the guiding rail 328 and a hole 332. In some implementations, the rotatable lever 318 is attached to the base (e.g., the base 308 of FIG. 3A) by a rotatable screw (e.g., the third screw 320 of FIG. 3A) through the hole 332. During operation, the rotatable lever 318 is configured to rotate with respect to (e.g., around) the rotatable screw along a plane (e.g., a horizontal plane or a vertical plane). Referring to FIG. 3B, the guiding rail 328 of the rotatable lever 318 defines a curved path such that a movement of the fastener 324 along the X direction is caused by a rotation of the rotatable lever 318. In some examples, a curved length of the curved path is in a range from 5 mm to 12 mm.

Referring to FIG. 3B, the rotatable lever 318 also includes a contact surface 334. The contact surface 334 can include one or more convex structures. During operation, the one or more convex structures of the contact surface 334 can increase friction between the operator and the rotatable lever 318. In other words, the contact surface 334 can help the operator rotate the rotatable lever 318 during operation.

As illustrated in FIG. 3C, the guiding pin 330 is on a first side 325-1 of the fastener 324. The fastener 324 also includes a first notch 336 and a second notch 338 on a second side 325-2 of the fastener 324. As shown in FIG. 3C, the first side 325-1 and the second side 325-2 of the fastener 324 are opposite to each other along the Z direction. In some implementations, the first notch 336 and the second notch 338 are arranged along the X direction and separated by a spacer 340.

In some implementations, the first notch 336 can be referred to as a secure notch. During operation, the first notch 336 is configured to secure the electronic component (e.g., the electronic component 210 of FIG. 2A) to the computing device (e.g., the computing device 200 of

FIG. 2A). For example, the first notch 336 is configured to secure the electronic component to the computing device when the fastener 324 is at the closed position, and the electronic component is removable from the computing device when the fastener 324 is at the open position.

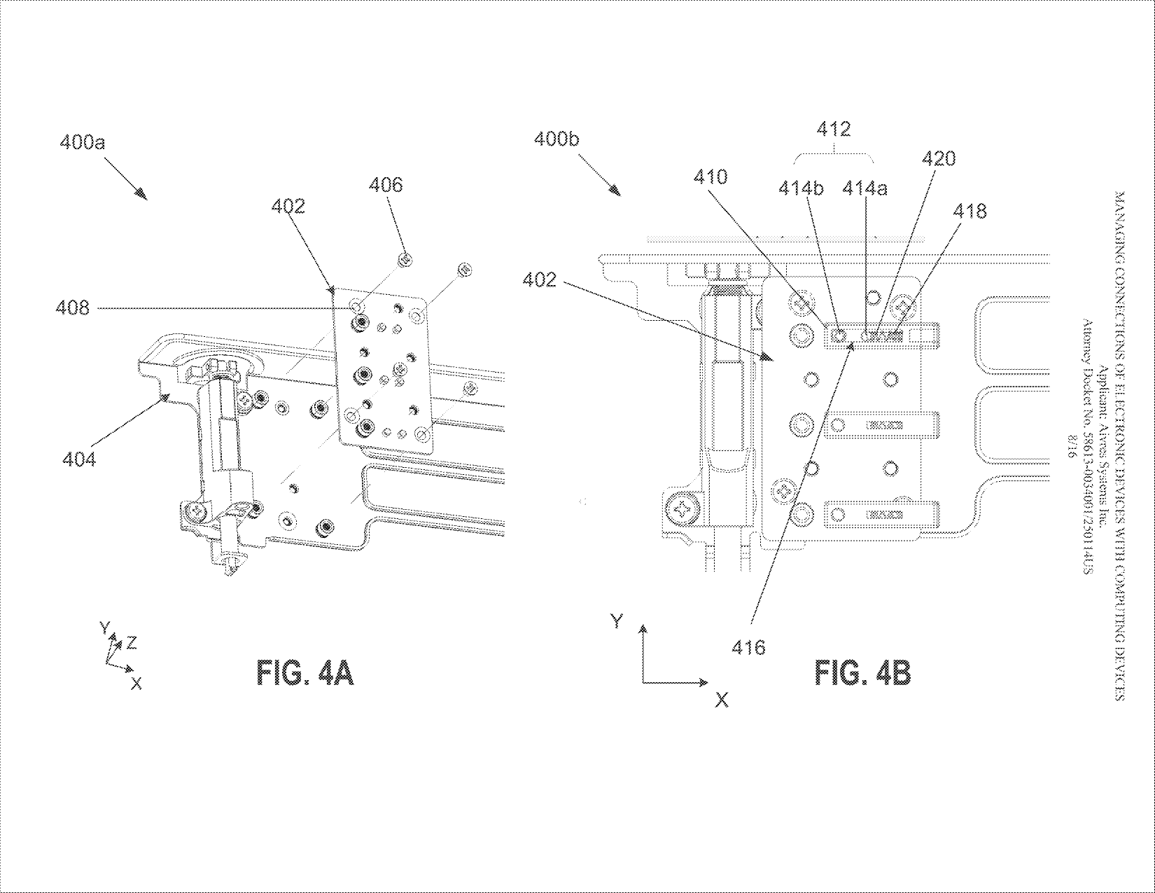

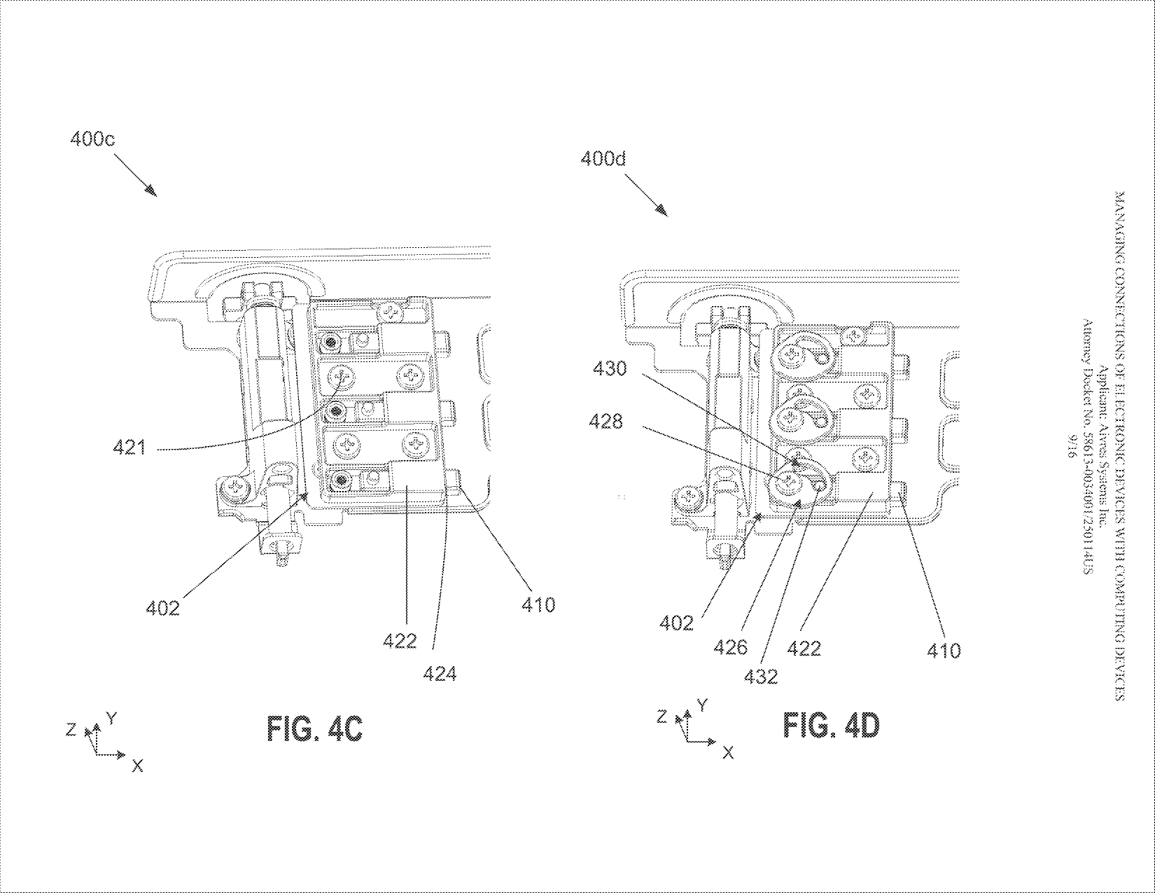

As shown in FIG. 3C, the fastener 324 further includes a positioning pole 342. The positioning pole 342 extends along the X direction and is attached to the spacer 340 along the X direction. In some implementations (as illustrated in FIG. 4B), the fastener 324 is coupled to the base 308 through the spring 326. The spring 326 is in contact with the spacer 340 and the base 308 along the X direction. In some implementations, the positioning pole 342 is surrounded by the spring 326.

Referring to FIG. 3D, the base 308 includes one or more riser holes 344 and one or more first locking holes 346. In some implementations, as shown in FIG. 3A, the base 308 is attached to the riser module 302 through the one or more first screws 312 and the cover 310 is attached to the base 308 by the one or more second screws 314. In some implementations, each of the one or more first screws 312 in configured to extend through a corresponding riser hole 344. In some implementations, each of the one or more second screws 314 is configured to extend through a corresponding first locking hole 346.

As illustrate in FIG. 3D, the base 308 further includes one or more pairs of positioning pins 348. The one or more pairs of positioning pins 348 are separated from each other along the Y direction. In some implementations, as shown in FIG. 3A, each pair of positioning pins 348 is surrounded by a corresponding guiding trench 316 of the cover 310.

In some implementations, each of the one or more pairs of positioning pins 348 includes at least a first pin 350a and a second pin 350b. The first pin 350a and the second pin 350b are arranged along the X direction. In some implementations, along the Y direction, a width of the first pin 350a is smaller than a width of the second notch 338 of the fastener 324. In some implementations, along the Y direction, a width of the second pin 350b is smaller than a width of the second notch 338 of the fastener 324. In some implementations, the first and second pins 350a and 350b are surrounded by the second notch 338 of a corresponding fastener 324.

Referring to FIG. 3A, the fastener 324 is coupled to the first pin 350a of a corresponding pair of positioning pins 348 through the spring 326. During operation, the spring 326 is in contact with the first pin 350a and the spacer 340 along the X direction.

In some implementations, during operation, the first pin 350a, the spring 326, and the positioning pole 342 are configured to limit a range of a first movement of the fastener 324 along the X direction. For example, during operation, the fastener 324 is configured to move from the closed position to the open position. At the open position, the spring 326 is compressed, and the positioning pole 342 contacts the corresponding first pin 350a along the X direction to prevent further movement of the fastener 324 beyond the open position. In some implementations, preventing further movement of the fastener 324 beyond the open position along the X direction can help avoid damage to the fastening device 304 during operation.

In some implementations, the second pin 350b is configured to limit a range of a second movement of the fastener 324 along the Y direction. For example, during operation, the second pin 350b is configured to guide a movement of the fastener 324 so that the fastener 324 can only move along the X direction. In other words, the second pin 350b can help ensure that the electronic component is secured by the first notch 336 of the fastener 324 when the fastener 324 is at the closed position.

As shown in FIG. 3D, the base 308 can also include one or more mounting holes 352. Referring to FIG. 3A, each of the rotatable levers 318 is attached to the base 308 through a corresponding third screw 320. In some implementations, the corresponding third screw 320 is configured to extend through a corresponding mounting hole 352.

Referring to FIG. 3E, the cover 310 includes one or more second locking holes 354. In some implementations (e.g., as shown in FIG. 3A and FIG. 3D), the cover 310 is attached to the base 308 through the second screws 314. In some implementations, each of the second screws 314 is configured to extend through a corresponding second locking hole 354 and the corresponding first locking hole 346.

As shown in FIG. 3E, the cover 310 also includes the one or more guiding trenches 316. The one or more guiding trenches 316 are separated from each other along the Y direction. Referring to FIG. 3A, each of the one or more fasteners 324 is coupled to a corresponding guiding trench 316. During operation, the fastener 324 is configured to move along the X direction in the corresponding guiding trench 316.

It is understood that FIGS. 3B – 3E are for illustration propose only, and the fastening device 304 can include any number of fasteners 324 attached to the base 308, where each of the

fasteners 324 is configured to secure a specific electronic component or disassemble the specific electronic component during operation.

FIGS. 4A – 4D illustrate steps of assembling an example fastening device. The example fastening device can be the fastening device 213 of FIG. 2B or the fastening device 304 of FIG. 3A. The fastening device can be assembled to a riser.

As shown in FIG. 4A, step 400a is performed. At step 400a, a base 402 (e.g., the base 308 of FIG. 3A) is attached to a riser module 404 (e.g., the riser module 211 of FIG. 2A or the riser module 302 of FIG. 3A) by first screws 406. As shown in FIG. 4A, the base 402 includes riser holes 408 (e.g., the riser holes 344 of FIG. 3D). In some implementations, each of the first screws 406 is configured to extend through a corresponding riser hole 408 to secure the base 402 to the riser module 404.

As shown in FIG. 4B, step 400b is performed. At step 400b, fasteners 410 (e.g., the fasteners 324 of FIG. 3A) are attached to the base 402. As illustrated in FIG. 4B, the base 402 includes one or more pairs of positioning pins 412 (e.g., the positioning pins 348 of FIG. 3D). The one or more pairs of positioning pins 412 are separated from each other along a second direction (e.g., the Y direction). Each of the pairs of positioning pins 412 includes a first pin 414a (e.g., the first pin 350a of FIG. 3D) and a second pin 414b (e.g., the second pin 350b of FIG. 3D). The first and second pins 414a and 414b are arranged along a first direction (e.g., the X direction) intersecting with the Y direction.

As shown in FIG. 4B, each of the fasteners 410 includes a notch 416 (e.g., the second notch 338 of FIG. 3C) and a positioning pole 418 (e.g., the positioning pole 342 of FIG. 3C). The fastener 410 is coupled to the base 402 through a spring 420 (e.g., the spring 326 of FIG. 3A). As illustrated in FIG. 4B, the spring 420 is in contact with the first pin 414a of a corresponding pair of positioning pins 412 and a sidewall of the notch 416 along the X direction. In some implementations, the positioning pole 418 is surrounded by the spring 420. In some implementations, the notch 416 surrounds the first and second pins 414a and 414b of the corresponding pair of positioning pins 412.

In some implementations, the first pin 414a, the positioning pole 418, and the spring 420 are configured to limit a range of a first movement of a corresponding fastener 410 along the X direction, and the second pin 414b is configured to limit a range of a second movement of the corresponding fastener 410 along the Y direction.

As shown in FIG. 4C, step 400c is performed. At step 400c, a cover 422 (e.g., the cover 310 of FIG. 3A) is attached to the base 402 by one or more second screws 421 (e.g., the second screws 314 of FIG. 3A). As illustrated in FIG. 4C, the cover 422 includes guiding trenches 424 (e.g., the guiding trenches 316 of FIG. 3A). In some implementations, each of the fasteners 410 is positioned in a corresponding guiding trench 424. In some implementations, the fastener 410 is configured to move along the X direction in the corresponding guiding trench 424.

As shown in FIG. 4D, step 400d is performed. At step 400d, rotatable levers 426 (e.g., the rotatable levers 318 of FIG. 3A) are attached to the base 402 by third screws 428 (e.g., the third screws 320 of FIG. 3A). As shown in FIG. 4D, the cover 422 is between the rotatable levers 426 and the base 402 along a third direction (e.g., the Z direction) perpendicular or substantially perpendicular to the X direction and the Y direction.

Each of the rotatable levers 426 include a guiding rail 430 (e.g., the guiding rail 328 of FIG. 3B) and each of the fasteners 410 includes a guiding pin 432 (e.g., the guiding pin 330 of FIG. 3D). In some implementations, as shown in FIG. 4D, the guiding pin 432 of each of the fasteners 410 is positioned within the guiding rail 430 of a corresponding rotatable lever 426.

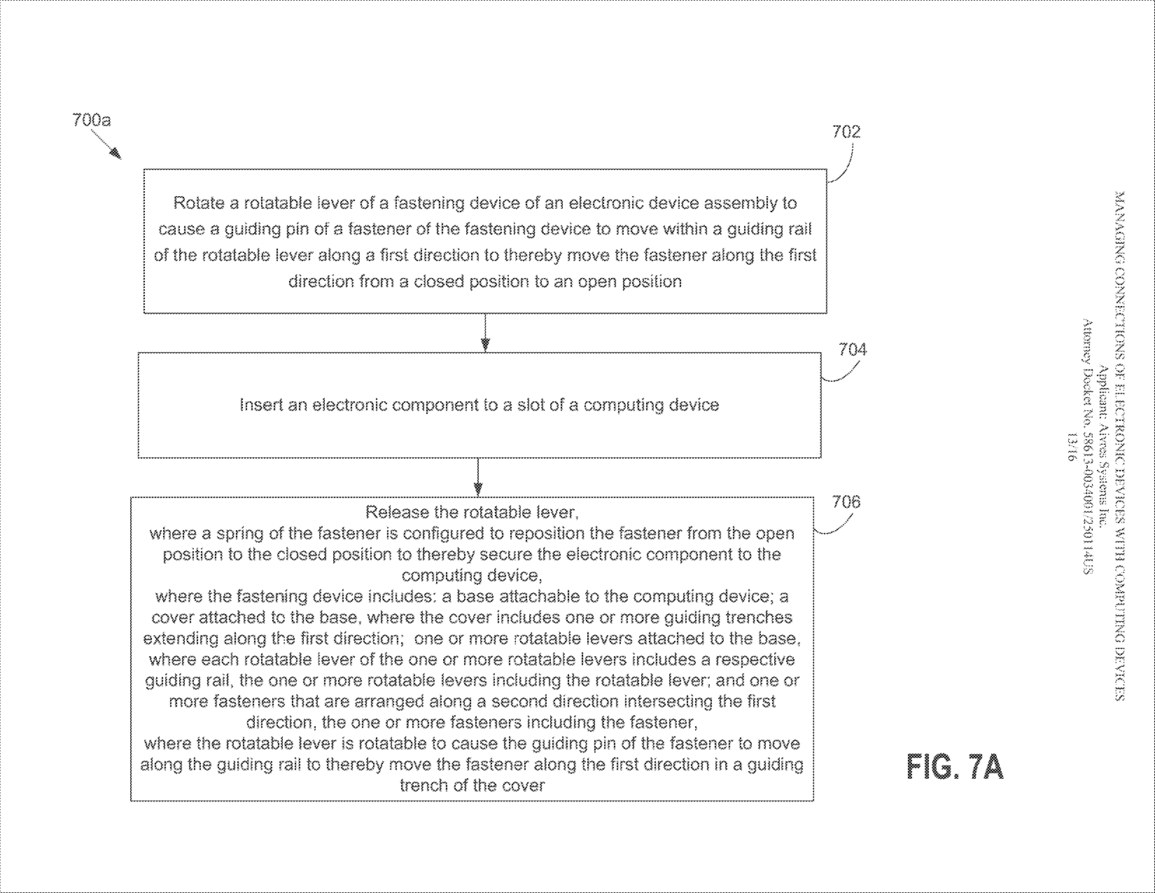

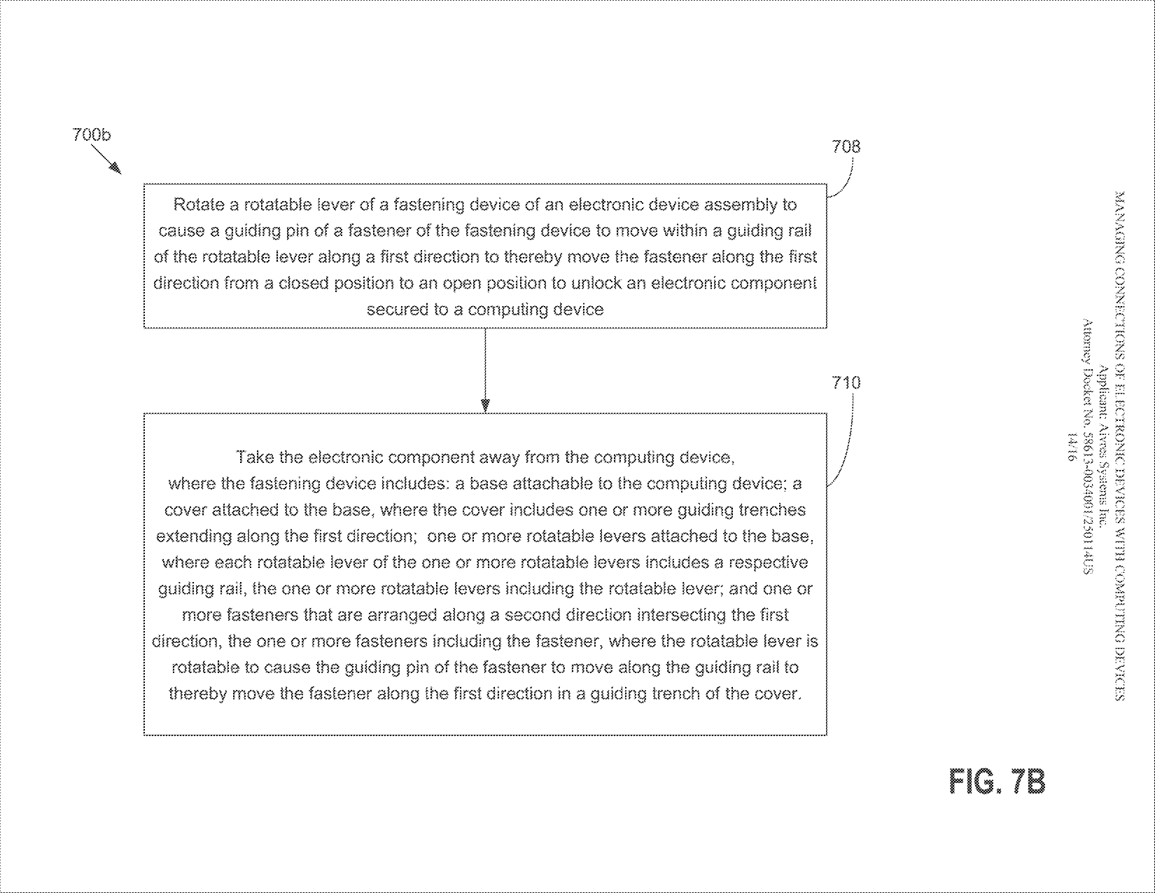

FIGS. 5A – 5B illustrate steps of assembling an electronic component to an electronic device assembly. FIG. 7A is a flowchart of an example process 700a of a method of assembling an electronic component to an electronic device assembly. In some implementations, the electronic component can be the electronic component 210 of FIG. 2A. In some implementations, the electronic device assembly can be the electronic device assembly 212 of FIG. 2B or the electronic device assembly 300 of FIG. 3A.

At operation 702, a rotatable lever (e.g., the rotatable lever 318 of FIG. 3A) of a fastening device (e.g., the fastening device 304 of FIG. 3A) of the electronic device assembly is rotated (e.g., by a robot arm or an operator) to cause a guiding pin (e.g., the guiding pin 330 of FIG. 3A) of a fastener (e.g., the fastener 324 of FIG. 3A) of the electronic device assembly to move within a guiding rail (e.g., the guiding rail 328 of FIG. 3A) of the rotatable lever along a first direction (e.g., the X direction) to thereby move the fastener along the first direction from a closed position to an open position.

At operation 704, an electronic component (e.g., the electronic component 210 of FIG. 2B) is inserted (e.g., by the robot arm or the operator) to a slot (e.g., the PCIe connector 209 of FIG. 2B) of a computing device (e.g., the computing device 200 of FIG. 2A).

For example, referring to FIG. 5A, step 500a is performed. As shown in FIG. 5A, an operator can rotate a rotatable lever 318 of a fastening device 502 (e.g., the fastening device 304 of FIG. 3A) to cause a guiding pin 330 of a fastener 324 of the fastening device 502 to move within a guiding rail of the rotatable lever 318 along the X direction to thereby move the fastener 324 along the X direction to an open position. As illustrated in FIG. 5A, the fastener 324 is at the open position.

As shown in FIG. 5A, at step 500a, the electronic component 210 is inserted into a corresponding PCIe connector 209 of the computing device by the operator. The electronic component includes a secure structure 220. In some implementations, the electronic component 210 is pushed down by the operator so that electrical pins 504 of the electronic component 210 are inserted into the corresponding PCIe connector 209.

Referring to FIG. 5A, the spring 326 of the fastener 324 is compressed along the X direction at the open position. In some implementations, the spring 326 is compressed by the fastener 324 and is configured to store an elastic force.

At operation 706, the rotatable lever is released (e.g., by the robot arm or the operator), wherein a spring (e.g., the spring 326 of FIG. 3A) of the fastener is configured to reposition the fastener from the open position to the close position to thereby secure the electronic component to the computing device. The fastening device includes: a base (e.g., the base 308 of FIG. 3A) attachable to the computing system; a cover (e.g., the cover 310 of FIG. 3A) attached to the base, one or more rotatable levers (e.g., the one or more rotatable levers 318 of FIG. 3A) attached to the base, and one or more fasteners (e.g., the one or more fasteners 324 of FIG. 3A) that are arranged along a second direction (e.g., the Y direction) intersecting the first direction. The cover includes one or more guiding trenches (e.g., the one or more guiding trenches 316 of FIG. 3A) extending along the first direction. Each rotatable lever of the one or more rotatable levers includes a respective guiding rail, the one or more rotatable levers including the rotatable lever. The one or more fasteners include the fastener. The rotatable lever is rotatable to cause the guiding pin of the fastener to move along the guiding rail to thereby move the fastener along the first direction in a guiding trench of the cover.

For example, referring to FIG. 5B, step 500b is performed. At step 500b, the rotatable lever 318 is released by the operator. The spring 326 releases the stored elastic force from step 500a and is configured to reposition the fastener 324 from the open position to the closed position.

As shown in FIG. 5B, the electronic component 210 is secured by the fastener 324. For example, at the closed position, a notch (e.g., the first notch 336 of FIG. 3C) of the fastener 324 is configured to lock onto the secure structure 220 of the electronic component. During operation, the notch of the fastener 324 is configured to prevent a movement of the electronic component through the notch and the secure structure 220.

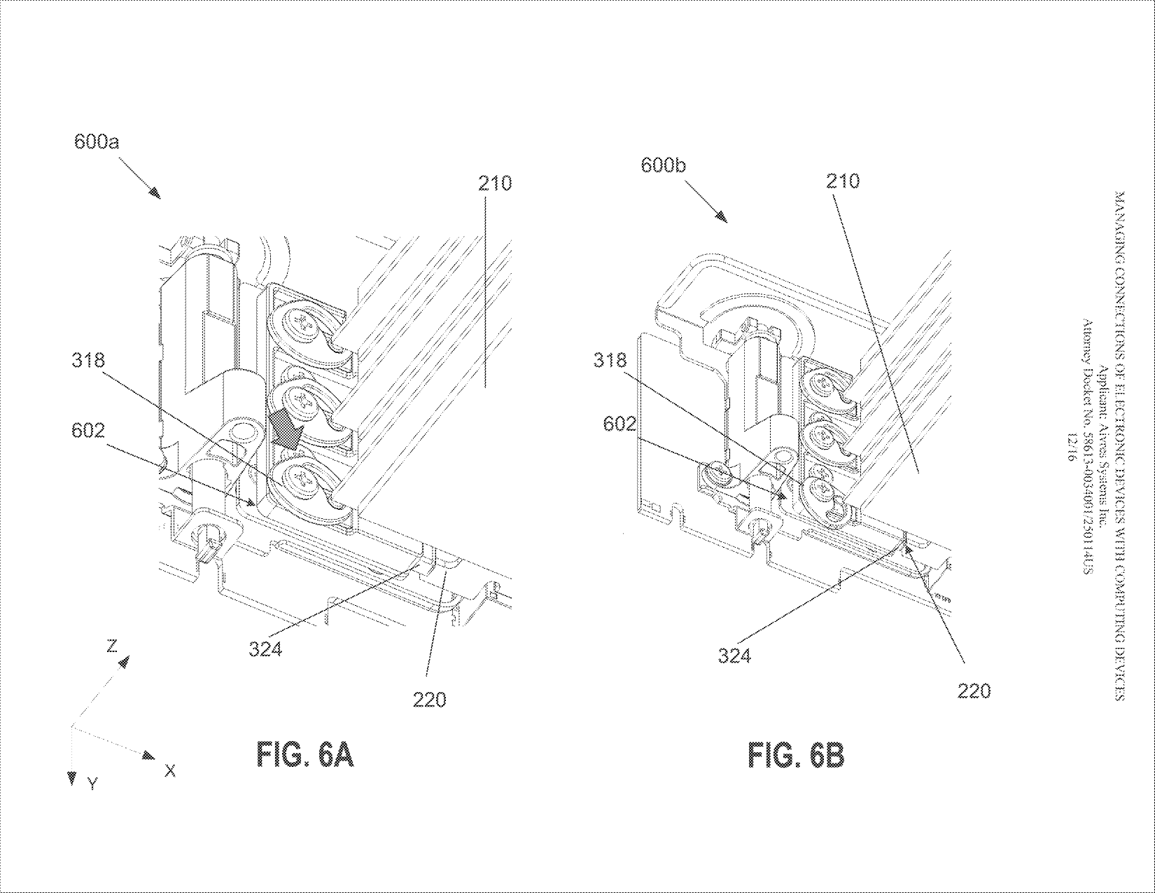

FIGS. 6A – 6B depict images steps of disassembling an electronic component from an electronic device assembly. FIG. 7B is a flowchart of an example process 700b of the method of assembling an electronic component from an electronic device assembly. In some implementations, the electronic component can be the electronic component 210 of FIG. 3A. In some implementations, the electronic device assembly can be the electronic device assembly 212 of FIG. 2B or the electronic device assembly 300 of FIG. 3A.

At operation 708, a rotatable lever (e.g., the rotatable lever 318 of FIG. 3A) of a fastening device (e.g., the fastening device 304 of FIG. 3A) of the electronic device assembly is rotated (e.g., by a robot arm or an operator) to cause a guiding pin (e.g., the guiding pin 330 of FIG. 3A) of a fastener (e.g., the fastener 324 of FIG. 3A) of the fastening device to move within a guiding rail (e.g., the guiding rail 328 of FIG. 3A) of the rotatable lever along a first direction (e.g., the X direction) to thereby move the fastener along the first direction from a closed position to an open position to unlock an electronic component secured to a computing device.

For example, referring to FIG. 6A, step 600a is performed. As shown in FIG. 6A, an operator can rotate a rotatable lever 318 of the fastening device 602 to cause a guiding pin 330 of a fastener 324 of the fastening device to move within a guiding rail 328 of the rotatable lever 318 along the X direction, thereby moving the fastener 324 along the X direction from a closed position toward an open position. As illustrated in FIG. 6A, the movement of the fastener 324 along the first direction is corresponding to a rotation of the rotatable lever 318 along a horizontal plane (e.g., the X-Y plane) perpendicular to the Z direction.

Referring to FIG. 6B, step 600b is performed. At step 600b, the fastener 324 is in the open position. The electronic component 210 that is secured to the computing device (e.g., the computing device 200 of FIG. 2A) is unlocked. As illustrated in FIG. 6A, at the open position, a notch (e.g., the first notch 336 of FIG. 3C) of the fastener 324 is moved toward the rotatable lever 318 to unlock a secure structure 220 of the electronic component 210.

At operation 710, the electronic component is taken away (e.g., by a robot arm or an operator) from the computing device. The fastening device includes: a base (e.g., the base 308 of FIG. 3A) attachable to the computing system; a cover (e.g., the cover 310 of FIG. 3A) attached to the base, one or more rotatable levers (e.g., the one or more rotatable levers 318 of FIG. 3A) attached to the base, and one or more fasteners (e.g., the one or more fasteners 324 of FIG. 3A) that are arranged along a second direction (e.g., the Y direction) intersecting the first direction. The cover includes one or more guiding trenches (e.g., the one or more guiding trenches 316 of FIG. 3A) extending along the first direction. Each rotatable lever of the one or more rotatable levers includes a respective guiding rail, the one or more rotatable levers including the rotatable lever. The one or more fasteners include the fastener. The rotatable lever is rotatable to cause the guiding pin of the fastener to move along the guiding rail to thereby move the fastener along the first direction in a guiding trench of the cover.

In some implementations, the cover is arranged between the base and the one or more rotatable levers, or the one or more rotatable levers are attached to the base through the cover.

In some implementations, the guiding rail of the rotatable lever defines a curved path such that a movement of the fastener along the first direction is caused by a rotation of the rotatable lever.

In some implementations, a degree of the rotation of the rotatable lever is in a range from 0° to 70°.

In some implementations, a curved length of the curved path is in a range from 5 mm to 12 mm, and where a length of the movement of the fastener along the first direction is in a range from 0 mm to 4 mm.

In some implementations, the rotatable lever includes a hole (e.g., the hole 332 of FIG. 3B).The rotatable lever is attached to the base by a rotatable screw (e.g., the third screw 320 of FIG. 3A) through the hole, and the rotatable lever is configured to rotate with respect to (e.g., around) the rotatable screw.

In some implementations, the cover is attached to the base by one or more locking screws (e.g., the second screws 314 of FIG. 3A).

In some implementations, the guiding pin is on a first side (e.g., the first side 325-1 of FIG. 3C) of the fastener. The fastener further includes a first notch (e.g., the first notch 336 of FIG. 3C) and a second notch (e.g., the second notch 338 of FIG. 3C) on a second side (e.g., the second

side 325-2 of FIG. 3C) of the fastener opposite to the first side along a third direction (e.g., the Z direction) perpendicular to the first direction and the second direction. The first notch and the second notch are arranged along the first direction and separated by a spacer (e.g., the spacer 340 of FIG. 3C).

In some implementations, the first notch is configured to secure the electronic component to the computing device. The fastener is configured to move between an open position and a closed position corresponding to a rotation of the rotatable lever, and the first notch is configured to secure the electronic component to the computing device when the fastener is at the closed position, and the electronic component is removable from the computing device when the fastener is at the open position.

In some implementations, the base includes one or more pairs of positioning pins (e.g., the one or more pairs of positioning pins 348 of FIG. 3D), the one or more pairs of positioning pins being separated from each other along the second direction, and each of the pairs of positioning pins includes at least a first pin (e.g., the first pin 350a of FIG. 3D) and a second pin (e.g., the second pin 350b of FIG. 3D) that are arranged along the first direction.

In some implementations, the fastener further includes a positioning pole (e.g., the positioning pole 342 of FIG. 3C) extending along the first direction in the second notch, the positioning pole being attached to the spacer along the first direction.

In some implementations, the fastener is coupled to the first pin of a corresponding pair of positioning pins of the base through a spring (e.g., the spring 326 of FIG. 3A). The spring in in contact with the first pin and the spacer along the first direction, and the positioning pole is surrounded by the spring.

In some implementations, the first pin, the spring, and the positioning pole are configured to limit a range of a first movement of the fastener along the first direction, and the second pin is configured to limit a range of a second movement of the fastener along the second direction.

In some implementations, the spring is configured to reposition the fastener along the first direction.

In some implementations, along the second direction, a width of the first pin is smaller than a width of the second notch, and where, along the second direction, a width of the second pin is smaller than the width of the second notch.

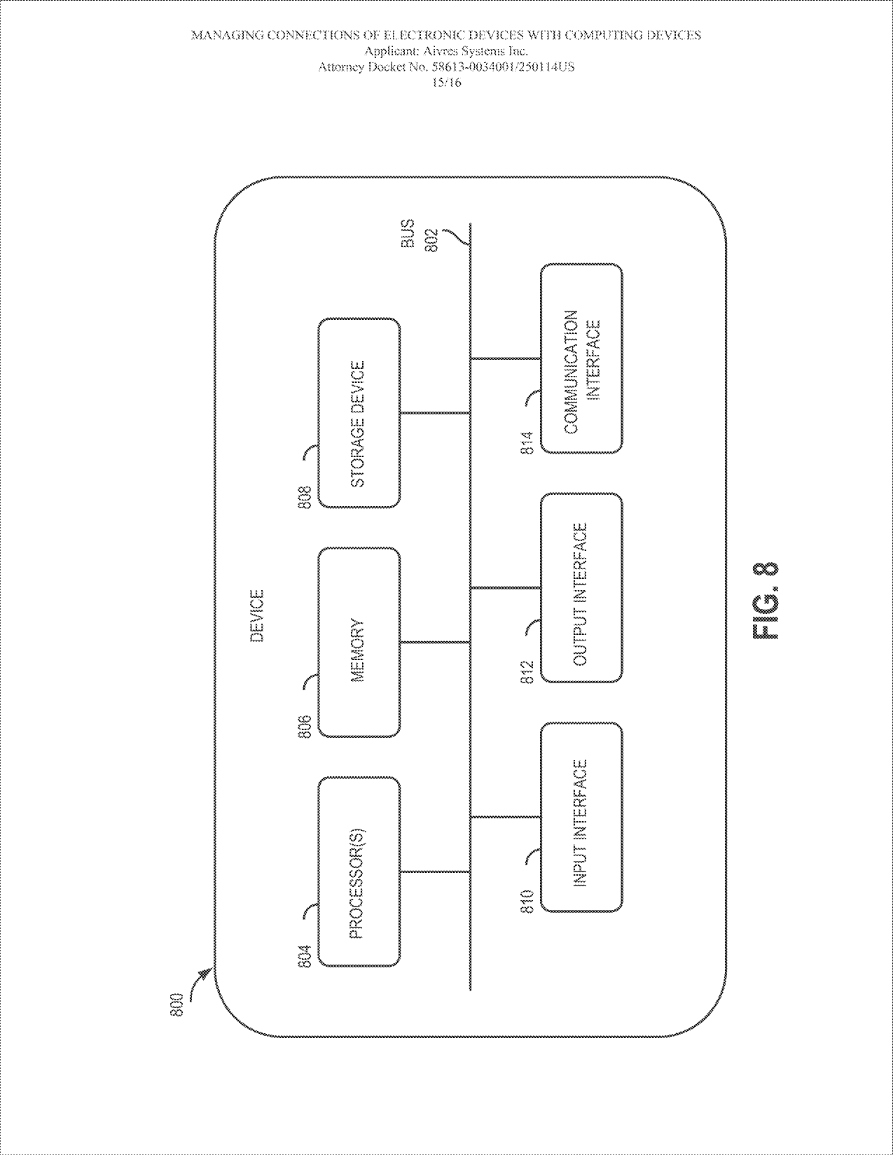

FIG. 8 is a block diagram illustrating an example architecture of a computing device 800 used to provide computational functionalities associated with described algorithms, methods, functions, processes, flows, and procedures. Other architectures are possible, including architectures with more or fewer components. The computing device can be implemented as the computing device 100 of FIG. 1 or the computing device 200 of FIG. 2A. The computing device 800 includes processor 804, memory 806, storage component 808, input interface 810, output interface 812, communication interface 814, and bus 802.

Bus 802 includes a component that permits communication among the components of the computing device 800. In some embodiments, processor 804 is implemented in hardware, software, or a combination of hardware and software. In some examples, processor 804 includes a processor (e.g., a central processing unit (CPU), a graphics processing unit (GPU), an accelerated processing unit (APU), and/or the like), a microphone, a digital signal processor (DSP), and/or any processing component (e.g., a field-programmable gate array (FPGA), an application specific integrated circuit (ASIC), and/or the like) that can be programmed to perform at least one function. Memory 806 includes random access memory (RAM), read-only memory (ROM), and/or another type of dynamic and/or static storage device (e.g., flash memory, magnetic memory, optical memory, and/or the like) that stores data and/or instructions for use by processor 804.

Storage component 808 stores data and/or software related to the operation and use of the computing device 800. In some examples, storage component 808 includes a hard disk (e.g., a magnetic disk, an optical disk, a magneto-optic disk, a solid state disk, and/or the like), a compact disc (CD), a digital versatile disc (DVD), a floppy disk, a cartridge, a magnetic tape, a CD-ROM, RAM, PROM, EPROM, FLASH-EPROM, NV-RAM, and/or another type of computer readable medium, along with a corresponding drive.

Input interface 810 includes a component that permits the computing device 800 to receive information, such as via user input (e.g., a touchscreen display, a keyboard, a keypad, a mouse, a button, a switch, a microphone, a camera, and/or the like). Additionally or alternatively, in some embodiments input interface 810 includes a sensor that senses information (e.g., a global positioning system (GPS) receiver, an accelerometer, a gyroscope, an actuator, and/or the like). Output interface 812 includes a component that provides output information from the computing device 800 (e.g., a display, a speaker, one or more light-emitting diodes (LEDs), and/or the like).

In some embodiments, communication interface 814 includes a transceiver-like component (e.g., a transceiver, a separate receiver and transmitter, and/or the like) that permits the computing device 800 to communicate with other devices via a wired connection, a wireless connection, or a combination of wired and wireless connections. In some examples, communication interface 814 permits the computing device 800 to receive information from another device and/or provide information to another device. In some examples, communication interface 814 includes an Ethernet interface, an optical interface, a coaxial interface, an infrared interface, a radio frequency (RF) interface, a universal serial bus (USB) interface, a Wi-Fi® interface, a cellular network interface, and/or the like.

In some embodiments, the computing device 800 performs one or more processes described herein. The computing device 800 performs these processes based on processor 804 executing software instructions stored by a computer-readable medium, such as memory 806 and/or storage component 808. A computer-readable medium (e.g., a non-transitory computer readable medium) is defined herein as a non-transitory memory device. A non-transitory memory device includes memory space located inside a single physical storage device or memory space spread across multiple physical storage devices.

In some embodiments, software instructions are read into memory 806 and/or storage component 808 from another computer-readable medium or another device via communication interface 814. When executed, software instructions stored in memory 806 and/or storage component 808 cause processor 804 to perform one or more processes described herein. Additionally or alternatively, hardwired circuitry is used in place of or in combination with software instructions to perform one or more processes described herein. Thus, embodiments described herein are not limited to any specific combination of hardware circuitry and software unless explicitly stated otherwise.

Memory 806 and/or storage component 808 includes data storage or at least one data structure (e.g., a database and/or the like). The computing device 800 is capable of receiving information from, storing information in, communicating information to, or searching information stored in the data storage or the at least one data structure in memory 806 or storage component 808. In some examples, the information includes network data, input data, output data, or any combination thereof.

In some embodiments, the computing device 800 is configured to execute software instructions that are either stored in memory 806 and/or in the memory of another device (e.g., another device that is the same as or similar to the computing device 800). As used herein, the term “module” refers to at least one instruction stored in memory 806 and/or in the memory of another device that, when executed by processor 804 and/or by a processor of another device (e.g., another device that is the same as or similar to the computing device 800) cause the computing device 800 (e.g., at least one component of the computing device 800) to perform one or more processes described herein. In some embodiments, a module is implemented in software, firmware, hardware, and/or the like.

The number and arrangement of components illustrated in FIG. 8 are provided as an example. In some embodiments, the computing device 800 can include additional components, fewer components, different components, or differently arranged components than those illustrated in FIG. 8. Additionally, or alternatively, a set of components (e.g., one or more components) of the computing device 800 can perform one or more functions described as being performed by another component or another set of components of the computing device 800.

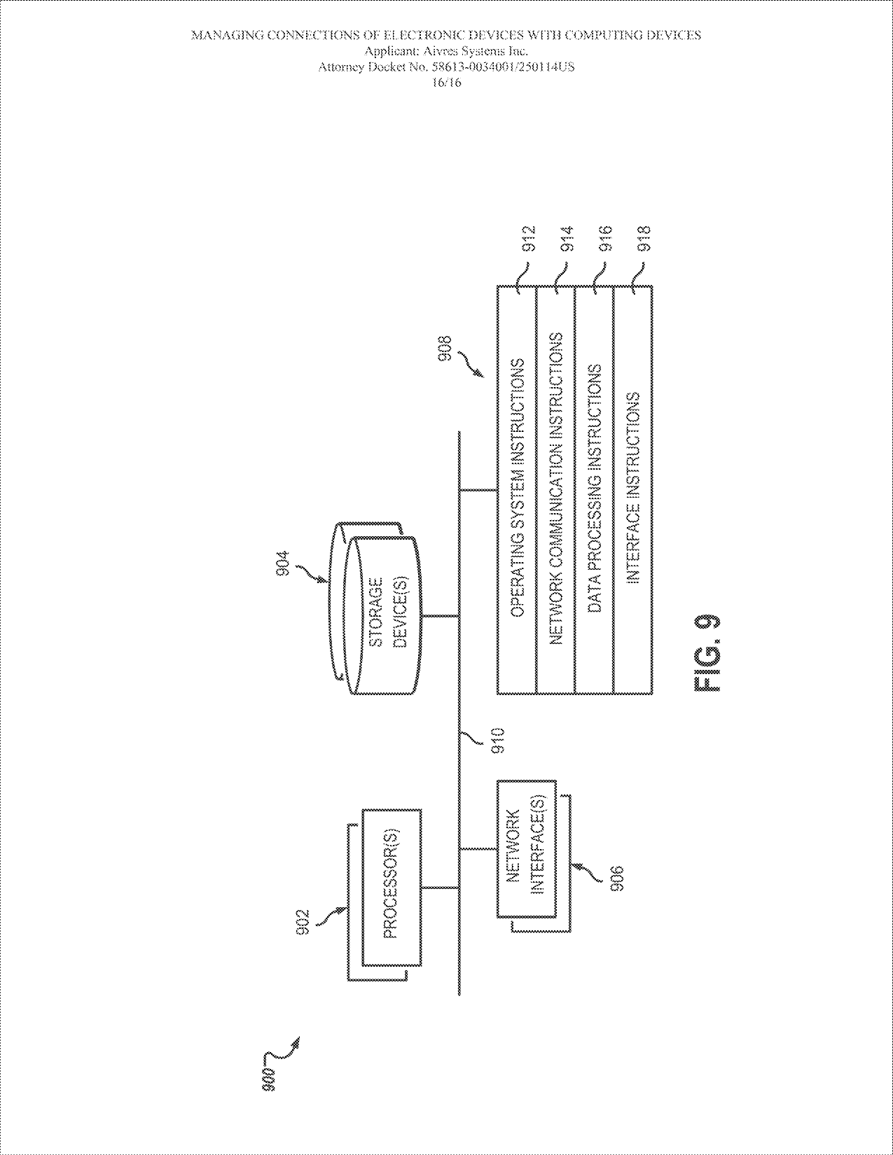

FIG. 9 illustrates an example architecture 900 of a computing system used to provide computational functionalities associated with described algorithms, methods, functions, processes, flows, and procedures. The computing system can include one or more computing devices such as the computing device 100 of FIG. 1 of the computing device 200 of FIG. 2A. Other architectures are possible, including architectures with more or fewer components.

In some implementations, architecture 900 includes one or more processor(s) 902 (e.g., dual-core Intel® Xeon® Processors), one or more network interface(s) 906, one or more storage device(s) 904 (e.g., hard disk, optical disk, flash memory) and one or more computer-readable medium(s) 908 (e.g., hard disk, optical disk, flash memory, etc.). These components can exchange communications and data over one or more communication channel(s) 910 (e.g., buses), which can utilize various hardware and software for facilitating the transfer of data and control signals between components.

The term “computer-readable medium” refers to any medium that participates in providing instructions to the processor(s) 902 for execution, including without limitation, non-volatile media (e.g., optical or magnetic disks), volatile media (e.g., memory) and transmission media. Transmission media includes, without limitation, coaxial cables, copper wire, and fiber optics.

Computer-readable medium(s) 908 can further include instructions 912 for an operating system (e.g., Mac OS® server, Windows® NT server, Linux Server), instructions 914 for network communications module, data processing instructions 916, and interface instructions 918.

Operating systems can be multi-user, multiprocessing, multitasking, multithreading, real time, etc. Operating system performs basic tasks, including but not limited to: recognizing input from and providing output to devices 902, 904, 906 and 908; keeping track and managing files and directories on computer-readable medium(s) 908 (e.g., memory or a storage device); controlling peripheral devices; and managing traffic on the one or more communication channel(s) 910. Network communications module includes various components for establishing and maintaining network connections (e.g., software for implementing communication protocols, such as TCP/IP, HTTP, etc.) and for creating a distributed streaming platform using, for example, Apache Kafka™. Data processing instructions 916 include server-side or backend software for implementing the server-side operations. Interface instructions 918 includes software for implementing a web server and/or portal for sending and receiving data to and from user side computing devices and service provider side computing devices.

Architecture 900 can be implemented by a cloud computing system and can be included in any computer device, including one or more server computers in a local or distributed network each having one or more processing cores. Architecture 900 can be implemented in a parallel processing or peer-to-peer infrastructure or on a single device with one or more processors. Software can include multiple software components or can be a single body of code.

Implementations of the subject matter and the functional operations described in this specification can be implemented in digital electronic circuitry, in tangibly embodied computer software or firmware, in computer hardware, including the structures disclosed in this specification and their structural equivalents, or in combinations of one or more of them. Software implementations of the described subject matter can be implemented as one or more computer programs, that is, one or more modules of computer program instructions encoded on a tangible, non-transitory, computer-readable medium for execution by, or to control the operation of, a computer or computer-implemented system. Alternatively, or additionally, the program instructions can be encoded in/on an artificially generated propagated signal, for example, a machine-generated electrical, optical, or electromagnetic signal that is generated to encode information for transmission to a receiver apparatus for execution by a computer or computer-implemented system. The computer-storage medium can be a machine-readable storage device, a machine-readable storage substrate, a random or serial access memory device, or a combination of computer-storage mediums. Configuring one or more computers means that the one or more computers have installed hardware, firmware, or software (or combinations of hardware, firmware, and software) so that when the software is executed by the one or more computers, particular computing operations are performed. The computer storage medium is not, however, a propagated signal.

The term “real-time,” “real time,” “realtime,” “real (fast) time (RFT),” “near(ly) real-time (NRT),” “quasi real-time,” or similar terms (as understood by one of ordinary skill in the art), means that an action and a response are temporally proximate such that an individual perceives the action and the response occurring substantially simultaneously. For example, the time difference for a response to display (or for an initiation of a display) of data following the individual’s action to access the data can be less than 1 millisecond (ms), less than 1 second (s), or less than 5 s. While the requested data need not be displayed (or initiated for display) instantaneously, it is displayed (or initiated for display) without any intentional delay, taking into account processing limitations of a described computing system and time required to, for example, gather, accurately measure, analyze, process, store, or transmit the data.

The terms “data processing apparatus,” “computer,” “computing device,” or “electronic computer device” (or an equivalent term as understood by one of ordinary skill in the art) refer to data processing hardware and encompass all kinds of apparatuses, devices, and machines for processing data, including by way of example, a programmable processor, a computer, or multiple processors or computers. The computer can also be, or further include special-purpose logic circuitry, for example, a central processing unit (CPU), a field-programmable gate array (FPGA), or an application-specific integrated circuit (ASIC). In some implementations, the computer or computer-implemented system or special-purpose logic circuitry (or a combination of the computer or computer-implemented system and special-purpose logic circuitry) can be hardware- or software-based (or a combination of both hardware- and software-based). The computer can optionally include code that creates an execution environment for computer programs, for example, code that constitutes processor firmware, a protocol stack, a database management system, an operating system, or a combination of execution environments. The present disclosure contemplates the use of a computer or computer-implemented system with an operating system, for example LINUX, UNIX, WINDOWS, MAC OS, ANDROID, or IOS, or a combination of operating systems.

A computer program, which can also be referred to or described as a program, software, a software application, a unit, a module, a software module, a script, code, or other component can be written in any form of programming language, including compiled or interpreted languages, or declarative or procedural languages, and it can be deployed in any form, including, for example, as a stand-alone program, module, component, or subroutine, for use in a computing environment. A computer program can, but need not, correspond to a file in a file system. A program can be stored in a portion of a file that holds other programs or data, for example, one or more scripts stored in a markup language document, in a single file dedicated to the program in question, or in multiple coordinated files, for example, files that store one or more modules, sub-programs, or portions of code. A computer program can be deployed to be executed on one computer or on multiple computers that are located at one site or distributed across multiple sites and interconnected by a communication network.

While portions of the programs illustrated in the various figures can be illustrated as individual components, such as units or modules, that implement described features and functionality using various objects, methods, or other processes, the programs can instead include a number of sub-units, sub-modules, third-party services, components, libraries, and other components, as appropriate. Conversely, the features and functionality of various components can be combined into single components, as appropriate. Thresholds used to make computational determinations can be statically, dynamically, or both statically and dynamically determined.

Described methods, processes, or logic flows represent one or more examples of functionality consistent with the present disclosure and are not intended to limit the disclosure to the described or illustrated implementations, but to be accorded the widest scope consistent with described principles and features. The described methods, processes, or logic flows can be performed by one or more programmable computers executing one or more computer programs to perform functions by operating on input data and generating output data. The methods, processes, or logic flows can also be performed by, and computers can also be implemented as, special-purpose logic circuitry, for example, a CPU, an FPGA, or an ASIC.

Computers for the execution of a computer program can be based on general or special-purpose microprocessors, both, or another type of CPU. Generally, a CPU will receive instructions and data from and write to a memory. The essential elements of a computer are a CPU, for performing or executing instructions, and one or more memory devices for storing instructions and data. Generally, a computer will also include, or be operatively coupled to, receive data from or transfer data to, or both, one or more mass storage devices for storing data, for example, magnetic, magneto-optical disks, or optical disks. However, a computer need not have such devices. Moreover, a computer can be embedded in another device, for example, a mobile telephone, a personal digital assistant (PDA), a mobile audio or video player, a game console, a global positioning system (GPS) receiver, or a portable memory storage device, for example, a universal serial bus (USB) flash drive, to name just a few.

Non-transitory computer-readable media for storing computer program instructions and data can include all forms of permanent/non-permanent or volatile/non-volatile memory, media and memory devices, including by way of example semiconductor memory devices, for example, random access memory (RAM), read-only memory (ROM), phase change memory (PRAM), static random access memory (SRAM), dynamic random access memory (DRAM), erasable programmable read-only memory (EPROM), electrically erasable programmable read-only memory (EEPROM), and flash memory devices; magnetic devices, for example, tape, cartridges, cassettes, internal/removable disks; magneto-optical disks; and optical memory devices, for example, digital versatile/video disc (DVD), compact disc (CD)-ROM, DVD+/-R, DVD-RAM, DVD-ROM, high-definition/density (HD)-DVD, and BLU-RAY/BLU-RAY DISC (BD), and other optical memory technologies. The memory can store various objects or data, including caches, classes, frameworks, applications, modules, backup data, jobs, web pages, web page templates, data structures, database tables, repositories storing dynamic information, or other appropriate information including any parameters, variables, algorithms, instructions, rules, constraints, or references. Additionally, the memory can include other appropriate data, such as logs, policies, security or access data, or reporting files. The processor and the memory can be supplemented by, or incorporated in, special-purpose logic circuitry.

To provide for interaction with a user, implementations of the subject matter described in this specification can be implemented on a computer having a display device, for example, a cathode ray tube (CRT), liquid crystal display (LCD), light emitting diode (LED), or plasma monitor, for displaying information to the user and a keyboard and a pointing device, for example, a mouse, trackball, or trackpad by which the user can provide input to the computer. Input can also be provided to the computer using a touchscreen, such as a tablet computer surface with pressure sensitivity or a multi-touch screen using capacitive or electric sensing. Other types of devices can be used to interact with the user. For example, feedback provided to the user can be any form of sensory feedback (such as, visual, auditory, tactile, or a combination of feedback types). Input from the user can be received in any form, including acoustic, speech, or tactile input. In addition, a computer can interact with the user by sending documents to and receiving documents from a client computing device that is used by the user (for example, by sending web pages to a web browser on a user’s mobile computing device in response to requests received from the web browser).

The term “graphical user interface (GUI) can be used in the singular or the plural to describe one or more graphical user interfaces and each of the displays of a particular graphical user interface. Therefore, a GUI can represent any graphical user interface, including but not limited to, a web browser, a touch screen, or a command line interface (CLI) that processes information and efficiently presents the information results to the user. In general, a GUI can include a number of user interface (UI) elements, some or all associated with a web browser, such as interactive fields, pull-down lists, and buttons. These and other UI elements can be related to or represent the functions of the web browser.

Implementations of the subject matter described in this specification can be implemented in a computing system that includes a back-end component, for example, as a data server, or that includes a middleware component, for example, an application server, or that includes a front-end component, for example, a client computer having a graphical user interface or a Web browser through which a user can interact with an implementation of the subject matter described in this specification, or any combination of one or more such back-end, middleware, or front-end components. The components of the system can be interconnected by any form or medium of wireline or wireless digital data communication (or a combination of data communication), for example, a communication network. Examples of communication networks include a local area network (LAN), a radio access network (RAN), a metropolitan area network (MAN), a wide area network (WAN), Worldwide Interoperability for Microwave Access (WIMAX), a wireless local area network (WLAN) using, for example, 802.11x or other protocols, all or a portion of the Internet, another communication network, or a combination of communication networks. The communication network can communicate with, for example, Internet Protocol (IP) packets, frame relay frames, Asynchronous Transfer Mode (ATM) cells, voice, video, data, or other information between network nodes.

The computing system can include clients and servers. A client and server are generally remote from each other and typically interact through a communication network. The relationship of client and server arises by virtue of computer programs running on the respective computers and having a client-server relationship to each other.

The separation or integration of various system modules and components in the previously described implementations should not be understood as requiring such separation or integration in all implementations, and it should be understood that the described program components and systems can generally be integrated together in a single software product or packaged into multiple software products.

Accordingly, the previously described example implementations do not define or constrain the present disclosure. Other changes, substitutions, and alterations are also possible without departing from the scope of the present disclosure.

Furthermore, any claimed implementation is considered to be applicable to at least a computer-implemented method; a non-transitory, computer-readable medium storing computer-readable instructions to perform the computer-implemented method; and a computer system including a computer memory interoperably coupled with a hardware processor configured to perform the computer-implemented method or the instructions stored on the non-transitory, computer-readable medium.

It is noted that references in the present disclosure to “one embodiment,” “an embodiment,” “an example embodiment,” “some implementations,” “some implementations,” etc., indicate that the embodiment described can include a particular feature, structure, or characteristic, but every embodiment can not necessarily include the particular feature, structure, or characteristic. Moreover, such phrases do not necessarily refer to the same embodiment. Further, when a particular feature, structure or characteristic is described in connection with an embodiment, it would be within the knowledge of a person skilled in the pertinent art to affect such feature, structure or characteristic in connection with other implementations whether or not explicitly described.

As used herein, the term “nominal/nominally” refers to a desired, or target, value of a characteristic or parameter for a component or a process step, set during the design phase of a product or a process, together with a range of values above and/or below the desired value. As used herein, the range of values can be due to slight variations in manufacturing processes or tolerances.

As used herein, the terms “a,” “an,” or “the” are used to include one or more than one unless the context clearly dictates otherwise. The term “or” is used to refer to a nonexclusive “or” unless otherwise indicated. The statement “at least one of A and B” has the same meaning as “A, B, or, A and B.” As used herein, the term “and/or” as used herein refers to and encompasses any and all possible combinations of one or more of the associated listed terms. For example, the term “A and/or B” means that either option A, option B, or both options A and B are possible, where A and B may be singular or plural.

As used herein, the term “about” or “approximately” can allow for a degree of variability in a value or range, for example, within 10%, within 5%, or within 1% of a stated value or of a stated limit of a range. As used herein, the term “substantially” refers to a majority of, or mostly, as in at least about 50%, 60%, 70%, 80%, 90%, 95%, 96%, 97%, 98%, 99%, 99.5%, 99.9%, 99.99%, or at least about 99.999% or more.

Values expressed in a range format should be interpreted in a flexible manner to include not only the numerical values explicitly recited as the limits of the range, but also to include all the individual numerical values or sub-ranges encompassed within that range as if each numerical value and sub-range is explicitly recited. For example, a range of “0.1% to about 5%” or “0.1% to 5%” should be interpreted to include about 0.1% to about 5%, as well as the individual values (for example, 1%, 2%, 3%, and 4%) and the sub-ranges (for example, 0.1% to 0.5%, 1.1% to 2.2%, 3.3% to 4.4%) within the indicated range. The statement “X to Y” has the same meaning as “about X to about Y,” unless indicated otherwise. Likewise, the statement “X, Y, or Z” has the same meaning as “about X, about Y, or about Z,” unless indicated otherwise.

In addition, the phraseology or terminology employed in the present disclosure, and not otherwise defined, is for the purpose of description only and not of limitation. Any use of section headings is intended to aid reading of the document and is not to be interpreted as limiting; information that is relevant to a section heading may occur within or outside of that particular section.

While this specification contains many specific implementation details, these should not be construed as limitations on the scope of any inventive concept or on the scope of what can be claimed, but rather as descriptions of features that can be specific to particular implementations of particular inventive concepts. Certain features that are described in this specification in the context of separate implementations can also be implemented, in combination, in a single implementation. Conversely, various features that are described in the context of a single implementation can also be implemented in multiple implementations, separately, or in any sub-combination. Moreover, although previously described features can be described as acting in certain combinations and even initially claimed as such, one or more features from a claimed combination can, in some cases, be excised from the combination, and the claimed combination can be directed to a sub-combination or variation of a sub-combination.

Particular implementations of the subject matter have been described. Other implementations, alterations, and permutations of the described implementations are within the scope of the following claims as will be apparent to those skilled in the art. While operations are depicted in the drawings or claims in a particular order, this should not be understood as requiring that such operations be performed in the particular order shown or in sequential order, or that all illustrated operations be performed (some operations can be considered optional), to achieve desirable results. In certain circumstances, multitasking or parallel processing (or a combination of multitasking and parallel processing) can be advantageous and performed as deemed appropriate.

The breadth and scope of the present disclosure should not be limited by any of the above-described exemplary implementations, but should be defined only in accordance with the following claims and their equivalents.

Claims:

1. A device, comprising:
a base attachable to a computing device;
a cover attached to the base, wherein the cover comprises one or more guiding trenches extending along a first direction;
one or more rotatable levers attached to the base, wherein each rotatable lever of the one or more rotatable levers comprises a respective guiding rail; and
one or more fasteners that are arranged along a second direction intersecting the first direction, wherein a fastener of the one or more fasteners comprises a guiding pin configured to be within a guiding rail of a rotatable lever, and wherein the rotatable lever is rotatable to cause the guiding pin of the fastener to move along the guiding rail to thereby move the fastener along the first direction in a guiding trench of the cover.

2. The device of claim 1, wherein the guiding rail of the rotatable lever defines a curved path such that a movement of the fastener along the first direction is caused by a rotation of the rotatable lever.

3. The device of claim 2, wherein a degree of the rotation of the rotatable lever is in a range from 0° to 70°.

4. The device of claim 2, wherein a curved length of the curved path is in a range from 5 mm to 12 mm, and wherein a length of the movement of the fastener along the first direction is in a range from 0 mm to 4 mm.

5. The device of claim 1, wherein the rotatable lever comprises a hole, wherein the rotatable lever is attached to the base by a rotatable screw through the hole, and wherein the rotatable lever is configured to rotate with respect to the rotatable screw.

6. The device of claim 1, wherein the guiding pin is on a first side of the fastener, wherein the fastener further comprises a first notch and a second notch on a second side of the fastener opposite to the first side along a third direction intersecting with the first direction and the second direction, and wherein the first notch and the second notch are arranged along the first direction and separated by a spacer.

7. The device of claim 6, wherein the first notch is configured to secure an electronic component to the computing system, and wherein the fastener is configured to move between an open position and a closed position corresponding to a rotation of the rotatable lever, and wherein the first notch is configured to secure the electronic component to the computing device when the fastener is at the closed position, and the electronic component is removable from the computing device when the fastener is at the open position.

8. The device of claim 6, wherein the base comprises one or more pairs of positioning pins, the one or more pairs of positioning pins being separated from each other along the second direction, and wherein each of the pairs of positioning pins comprises at least a first pin and a second pin that are arranged along the first direction.

9. The device of claim 8, wherein the fastener further comprises a positioning pole extending along the first direction in the second notch, the positioning pole being attached to the spacer along the first direction.

10. The device of claim 9, wherein the fastener is coupled to the first pin of a corresponding pair of positioning pins of the base through a spring, wherein the spring is in contact with the first pin and the spacer along the first direction, and wherein the positioning pole is surrounded by the spring.

11. The device of claim 10, wherein the first pin, the spring, and the positioning pole are configured to limit a range of a first movement of the fastener along the first direction, and wherein the second pin is configured to limit a range of a second movement of the fastener along the second direction.

12. The device of claim 10, wherein the spring is configured to reposition the fastener along the first direction.

13. The device of claim 9, wherein, along the second direction, a width of the first pin is smaller than a width of the second notch, and wherein, along the second direction, a width of the second pin is smaller than the width of the second notch.

14. An electronic device assembly, comprising:
a riser module attachable to a computing device; and
a fastening device configured to secure at least one electronic component to the riser module, wherein the fastening device comprises:
a base attachable to the riser module;
a cover attached to the base, wherein the cover comprises one or more guiding trenches extending along a first direction;
one or more rotatable levers attached to the base, wherein each rotatable lever of the one or more rotatable levers comprises a respective guiding rail; and
one or more fasteners that are arranged along a second direction intersecting the first direction, wherein a fastener of the one or more fasteners comprises a guiding pin configured to be within a guiding rail of a rotatable lever, and wherein the rotatable lever is rotatable to cause the guiding pin of the fastener to move along the guiding rail to thereby move the fastener along the first direction in a guiding trench of the cover.

15. The electronic device assembly of claim 14, wherein the guiding rail of the rotatable lever defines a curved path such that a movement of the fastener along the first direction is caused by a rotation of the rotatable lever.

16. The electronic device assembly of claim 15, wherein a degree of the rotation of the rotatable lever is in a range from 0° to 70°,
wherein a curved length of the curved path is in a range from 5 mm to 12 mm, and
wherein a length of the movement of the fastener along the first direction is in a range from 0 mm to 4 mm.

17. The electronic device assembly of claim 14, wherein the rotatable lever comprises a hole, wherein the rotatable lever is attached to the base by a rotatable screw through the hole, and wherein the rotatable lever is configured to rotate with respect to the rotatable screw.

18. The electronic device assembly of claim 14, wherein the guiding pin is on a first side of the fastener,
wherein the fastener further comprises a first notch and a second notch on a second side of the fastener opposite to the first side along a third direction perpendicular to the first direction and the second direction, and
wherein the first notch and the second notch are arranged along the first direction and separated by a spacer, and wherein the first notch is configured to secure an electronic component to the riser module.

19. The electronic device assembly of claim 18, wherein the fastener is configured to move between an open position and a closed position corresponding to a rotation of the rotatable lever, and
wherein the first notch is configured to secure the electronic component to the computing device when the fastener is at the closed position, and the electronic component is removable from the computing device when the fastener is at the open position.

20. A method, comprising:
rotating a rotatable lever of a fastening device to cause a guiding pin of a fastener of the fastening device to move within a guiding rail of the rotatable lever along a first direction to thereby move the fastener along the first direction from a closed position to an open position to unlock an electronic component secured to a computing device; and
taking the electronic component away from the computing device,
wherein the fastening device comprises:
a base attachable to the computing device;
a cover attached to the base, wherein the cover comprises one or more guiding trenches extending along the first direction;
one or more rotatable levers attached to the base, wherein each rotatable lever of the one or more rotatable levers comprises a respective guiding rail, the one or more rotatable levers comprising the rotatable lever; and
one or more fasteners that are arranged along a second direction intersecting the first direction, the one or more fasteners comprising the fastener,
wherein the rotatable lever is rotatable to cause the guiding pin of the fastener to move along the guiding rail to thereby move the fastener along the first direction in a guiding trench of the cover.
